(19) United States
(12) Patent Application Publication
(10) Pub. No.: US 2025/0105828 A1
(43) Pub. Date: Mar. 27, 2025

(54) Quantized Bistable Resistively-coupled Ising Machine

(71) Applicant: University of Rochester, Rochester, NY (US)

(72) Inventors: Zeljko Ignjatovic, Rochester, NY (US); Yiqiao Zhang, Rochester, NY (US)

(21) Appl. No.: 18/728,224

(22) PCT Filed: Jan. 12, 2023
(86) PCT No.: PCT/US2023/060567

§ 371 Date: Jul. 11, 2024

Related U.S. Application Data
(60) Provisional application No. 63/298,859, filed on Jan. 12, 2022.

(51) Int. Cl. H03K 3/037; H03K 19/21

(52) U.S. Cl. CPC H03K 3/037; H03K 19/21

(57) ABSTRACT

A computation node comprises an input, an output, a bistable node, comprising an input and an output, the output configured to have at least two equilibrium output voltages, a first buffer circuit, having an input and an output, the buffer input connected to the bistable node and the buffer output connected to the computation node, the buffer circuit configured to provide a first output voltage when a voltage at the buffer input is below a threshold, and a second output voltage when the voltage at the buffer input is above the threshold, and a current conveyor node having an input connected to the computation node and an output connected to the bistable node, the current conveyor configured to hold its input at a constant voltage and mirror current received at the input into the input of the bistable node. A network of resistively-coupled computation nodes is also described.

### CROSS-REFERENCE TO RELATED APPLICATIONS

This application is a U.S. national phase application filed under 35 U.S.C. § 371 claiming benefit to International Patent Application No. PCT/US2023/060567, filed Jan. 12, 2023, which claims priority to U.S. Provisional Application No. 63/298,859 filed on Jan. 12, 2022, incorporated herein by reference in its entirety.

### BACKGROUND OF THE INVENTION

For a long time, the industry focused on improving general-purpose systems and improving the power of computing by orders of magnitude. But in recent years, special-purpose designs have been increasingly adopted for their efficacy in solving specific types of tasks such as encryption and network operations. At the same time, computations require better mechanisms to solve a wide array of modern problems. Machine learning tasks have become a new focus and many specialized architectures are proposed to accelerate their operations.

Many accelerator architectures have been proposed. They have low operation costs and control overheads, but most are largely within the von Neumann regime. In a related but different track of work, researchers are trying to leverage physical processes that evolves to a final state which naturally corresponds to a solution to some problem. In principle, such nature-based computing systems can be significantly better in performance and efficiency than conventional accelerators. Hence, there is much interest about these systems, particularly in the physics community. Quantum computers marketed by D-Wave Systems are prominent examples, but many other prototypes exist, and some are already showing exciting capabilities.

In a nutshell, the Ising model concerns a system with many nodes (e.g., atoms), each with a spin (σᵢ) which takes one of two values (+1,−1). Every pair of spins (σᵢ and σⱼ) has a specific coupling coefficient (Jᵢⱼ) and each spin also interacts with external field μ with coefficient hᵢ. The total energy of the system is thus given by the Ising formula,

$$H = - {\sum }_{1 \leq i < j \leq N} {J}_{i j} {σ}_{i} {σ}_{j} - μ {\sum }_{i = 1} {h}_{i} {σ}_{i} \qquad Equation 1$$

or if we ignore the external field, the Hamiltonian simplifies to

$$H = - {\sum }_{i < j} {J}_{i j} {σ}_{i} {σ}_{j} \qquad Equation 2$$

This simplified version is more useful for the purpose of the present disclosure. Henceforth, when “the Ising model” or Ising formula, will refer to Equation 2.

A physical system with such a Hamiltonian naturally tends towards low-energy states. Hence it can be used to solve an optimization problem with a formulation equivalent to the Ising formula if parameters can be selected (e.g. Jᵢⱼ) to match that of the problem.

Many optimization problems naturally map to an Ising machine. Perhaps the most straightforward problem to map is the Max-Cut problem. Given a graph, G=(V,E), a “cut” is a partition of vertices into two sets of, say, V⁺ and V⁻, where V⁻=V−V⁺. The goal is to find a cut such that the combined weight of the edges spanning the two sets of vertices is maximum. In other words, the maximum cut is

$${arg max}_{{V}^{+} ∈ ℙ ( V )} ( {E}_{( i , j ) ∈ E ; i ∈ {V}^{+} ; j ∈ {V}^{-}} {W}_{ij} ) \qquad Equation 3$$

where Wᵢⱼ is the weight of the edge (i,j).

It is easy to see the resemblance between Equation 2 and Equation 3.

If the coupling weight (Jᵢⱼ) is set to be the negative of edge weight (−Wᵢⱼ) then the Ising formula is simply twice the negative cut value plus a problem-specific constant (ΣWᵢⱼ) as follows (for notational simplicity, for i≥j, Wᵢⱼ is set to 0):

$$H = \sum {J}_{ij} {σ}_{i} {σ}_{j} = {\sum }_{{σ}_{i} = - {σ}_{j}} {W}_{i j} {σ}_{i} {σ}_{j} + {\sum }_{{σ}_{i} = {σ}_{j}} {W}_{ij} {σ}_{i} {σ}_{j} = - {\sum }_{{σ}_{i} = - {σ}_{j}} {W}_{i j} + {\sum }_{{σ}_{i} = {σ}_{j}} {W}_{ij} = - 2 {\sum }_{{σ}_{i} = - {σ}_{j}} {W}_{ij} + \sum {W}_{ij} \qquad Equation 4$$

Hence if the machine finds the ground state of the Hamiltonian, it will return the maximum cut. Finding out the maximum cut of an arbitrary graph is an NP-hard problem. Practical algorithms only try to find a good answer. Similarly, existing Ising machines (including the disclosed design) are all Ising sampling machines that typically provide a good sample of a low-energy state, with no guarantee of optimality.

Because of the trivial mapping of the Max-Cut problem to the Ising formula, designers of Ising machines often focus on this optimization problem. However, other optimization problems can also be mapped to an Ising machine.

Building a fully programmable spin-system, however, is a challenging task: different realizations of spin-systems so far all have some non-trivial drawbacks (e.g., requiring cryogenic operating conditions), which manifest to end users as high operating costs and/or limited problem-solving capabilities. The recently-disclosed bistable resistively-coupled Ising Machine (BRIM) design is the first major drawback-free Ising machine. More information about BRIM may be found in U.S. patent application Ser. No. 17/996,283, filed on Oct. 14, 2022; International Application No. PCT/US2021/070402, filed on Apr. 16, 2021, and U.S. Provisional Application No. 63/011,245, filed on Apr. 16, 2020, all of which are incorporated herein by reference.

To facilitate computation for diverse workloads, researchers are trying to map an entire algorithm to physical processes such that the resulting state represents an answer to the mapped algorithm. An example is Quantum annealer from D-Wave Systems (Bunyk, et al., IEEE

Transactions on Applied Superconductivity, 2014). where a combinatorial optimization problem is mapped to a system of qubits such that the system's Hamiltonian is subjected to minimization. Careful control is required for the system to settle to an equilibrium (i.e. optimal solution), and the qubit states are read out as the solution to the mapped problem.

It is not definitive whether D-Wave's systems can reach some sort of quantum speedup, but it is clear that these Ising machines can indeed find some good solutions to an optimization problem in a very short amount of time (milli- or micro-second latencies). Recently, there have been designs that show good quality solutions for non-trivial sizes. The common properties of Ising machines is that: a problem is mapped to its physical setup, the internal state evolves according to machine-dependent physics, the evolution optimizes a particular formula (the Ising model), and the machine's physical state is read out to achieve a solution to the mapped problem.

Different from the von Neumann machine, these nature-based machines follow no explicit algorithm: nature is effectively carrying out the computation. Recently, diverse Ising machines have been implemented in a variety of ways. They differ in complexity of their underlying physics principles, and it is not clear whether any form provides a fundamental advantage over others in a large-scale system. It is noted that these machines are not guaranteed to reach the ground state (the optimal solution) in practice. Rather, they can find good solutions at high speed, and with good overall energy efficiency.

Despite their potential of outperforming conventional computers in terms of power and time to find solutions, building a robust and general Ising machine substrate remains challenging and scalability is one of the key factors that need to be considered. As the complexity of the problem to solve increases, the amount of required hardware components grows exponentially. In order to sustain a small form factor and chip area comparable to (or better than) a conventional computing substrate, simple building blocks are preferred for an Ising machine's implementation. Disclosed herein is a resistively-coupled Ising machine with bistable nodes and quantized nodal interactions (QuBRIM), which reduces the hardware complexity by directly adjusting the interactions among neighboring nodes.

To understand the rationale behind the disclosed designs, the present disclosure first analyzes why all-to-all coupling is essential by showing in more detail the true costs of near-neighbor coupling (see below). Having all-to-all coupling per se is not enough. After all, one can simulate any system with von Neumann computation. It is shown herein that such emulation is inefficient both in terms of time and energy cost. Only physical all-to-all coupling can make a dynamical system perform computation at speeds orders of magnitude faster than conventional computation.

### SUMMARY OF THE INVENTION

In one aspect, a computation node comprises an input, an output, a bistable node comprising an input and an output, the output configured to have at least two equilibrium output voltages, a first buffer circuit, having an input and an output, the buffer input connected to the output of the bistable node and the buffer output connected to the output of the computation node, the buffer circuit configured to provide a first output voltage when a voltage at the buffer input is below a threshold, and a second output voltage when the voltage at the buffer input is above the threshold, and a current conveyor node having an input connected to the input of the computation node and an output connected to the input of the bistable node, the current conveyor configured to hold its input at a constant voltage and mirror current received at the input into the input of the bistable node.

In one embodiment, the first buffer circuit comprises an inverter. In one embodiment, the computation node further comprises a second, inverting output and a second buffer circuit having an input connected to an inverting output of the bistable node, the inverting output of the bistable node configured to have an inverse value of the output of the bistable node, the second buffer circuit further comprising an output connected to the second inverting output of the computation node. In one embodiment, the first and second buffer circuits each comprise an inverter. In one embodiment, the computation node further comprises a second, inverting input; and a second current conveyor node having an input connected to the second inverting input of the computation node and an output connected to a second input of the bistable node, the current conveyor configured to hold its input at a constant voltage and mirror current received at the input into the second input of the bistable node.

In one aspect, a network comprises at least first and second computation nodes as defined herein, further comprising a coupling node connecting the output of the first computation node to the input of the second computation node. In one embodiment, the coupling node comprises a resistor. In one embodiment, the coupling node comprises a pseudo-resistor.

In one aspect, a network of resistively-coupled computation nodes comprises at least one computation node, each comprising an input, an output, a bistable node, comprising an input and an output, the output configured to have at least two equilibrium output voltages, a first inverter having an input and an output, the inverter input connected to the output of the bistable node and the inverter output connected to the output of the computation node, and a current conveyor node having an input connected to the input of the computation node and an output connected to the input of the bistable node, and a resistive coupling connected to the output of the computation node.

In one embodiment, the at least one computation node comprises first and second computation nodes, wherein the input of the second computation node is connected to the input of the first computation node. In one embodiment, the output of the first computation node and the output of the second computation node are connected to a multiplication node configured to multiply the outputs and provide the multiplied output as a multiplication node output. In one embodiment, the multiplication node comprises an exclusive NOR gate.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is an exemplary computing device.

FIG. 2A is a graph of Total physical nodes required for diverse logical node sizes.

FIG. 2B is a graph of Execution time for embedding.

FIG. 3 is a graph of solution quality measured as distance from ground states for two near-neighbor-coupled Ising machines. All systems have 20 us annealing time. Solid lines represent averages, and shaded regions represent range of result from 50 runs for each problem.

FIG. 4A and FIG. 4B are graphs showing the impact of local coupling architecture on solution quality. Five different sizes of graphs are generated, ranging from 16 to 32 nodes. These graphs are then minor-embedded to generate a target topology for Chimera-connection machines (e.g., D-Wave). All physical spins mapping to a single logical spin are coupled together with a parameterized strength k (x-axes). FIG. 4A shows the percentage of the chains (physical spins representing the same logical spins) that are broken. FIG. 4B graphs plot the distance of the solution's energy from that of the ground state of the problem. Lower differences are better.

FIG. 5A is a Sample Max-Cut problem mapping to a 4-node resistive Ising machine.

FIG. 5B is a graph of the corresponding solution to the machine of FIG. 5A, a cut value of +4.5.

FIG. 6A is a simplified schematic of one BRIM node.

FIG. 6B is a graph of a ZIV diode's IV characteristic.

FIG. 6C is a diagram of an example ZIV diode CMOS implementation.

FIG. 7 is a graph showing a potential well of a bistable node.

FIG. 8 is a block diagram of BRIM system components. The multi-colored links are interconnect lines, where red and blue lines represent positive and negative nodal terminals, respectively.

FIG. 9 shows two back-to-back PMOS devices that form a pseudo resistor, the equivalent resistance is controlled by V_{ctr}, and the bottom graph shows the I-V characteristics of pseudo-resistor under different V_{ctr}, where the inverse of the slope represents the resistance.

FIG. 10 shows a schematic of BRIM coupling units (Left: Parallel CU; Right: Anti-parallel CU). The color scheme of the interconnect lines IN″, IN, V_{dae}, and CS are matched to the system-level block diagram in FIG. 9, where CS is a column select signal generated by the BRIM's column selector unit.

FIG. 11 is a set of graphs showing the trade-off between the strength of ZIV diode and the scaling resistance R_{c}.

FIG. 12 is a schematic of an exemplary QuBRIM node. CCCS stands for current-controlled current-source implemented here as a current conveyor. Transistors M₁₁ and M₁₆ maintain constant voltages at the current summing nodes IN+ and IN−.

FIG. 13 is a block diagram showing components of a QuBRIM. In the diagram, nodes are labeled Nᵢ and coupling units CUᵢⱼ.

FIG. 14 is a schematic of a half-circuit of one exemplary QuBRIM node.

FIG. 15 is a schematic view of an exemplary QuBRIM coupling unit. On the right is an implementation of the programmable coupling resistor, where V_{ctr} is the biasing voltage.

FIG. 16 is a graph of a cumulative Probability Distribution of distance from the best Max-Cut for 32-node graphs for a simulation time of 200 ns. Note that the best Max-Cut for a 32-node graph is found by enumerating and comparing all 2³² possible solutions.

FIG. 17 is a graph of solution quality of different Ising machines. All systems have 20 us annealing time. Solid lines represent averages, and shaded regions represent range

FIG. 18 is a set of graphs The top graph shows Ising energy vs. time, and the bottom graph is the transient voltage of each node. The machine reaches a local minimum at roughly 15 ns (dashed section), then spin-fix annealing kicks in (solid section).

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of +20%, +10%, +5%, +1%, and +0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

In some aspects of the present invention, software executing the instructions provided herein may be stored on a non-transitory computer-readable medium, wherein the software performs some or all of the steps of the present invention when executed on a processor.

Aspects of the invention relate to algorithms executed in computer software. Though certain embodiments may be described as written in particular programming languages, or executed on particular operating systems or computing platforms, it is understood that the system and method of the present invention is not limited to any particular computing language, platform, or combination thereof. Software executing the algorithms described herein may be written in any programming language known in the art, compiled or interpreted, including but not limited to C, C++, C#, Objective-C, Java, JavaScript, MATLAB, Python, PHP, Perl, Ruby, or Visual Basic. It is further understood that elements of the present invention may be executed on any acceptable computing platform, including but not limited to a server, a cloud instance, a workstation, a thin client, a mobile device, an embedded microcontroller, a television, or any other suitable computing device known in the art.

Parts of this invention are described as software running on a computing device. Though software described herein may be disclosed as operating on one particular computing device (e.g. a dedicated server or a workstation), it is understood in the art that software is intrinsically portable and that most software running on a dedicated server may also be run, for the purposes of the present invention, on any of a wide range of devices including desktop or mobile devices, laptops, tablets, smartphones, watches, wearable electronics or other wireless digital/cellular phones, televisions, cloud instances, embedded microcontrollers, thin client devices, or any other suitable computing device known in the art.

Similarly, parts of this invention are described as communicating over a variety of wireless or wired computer networks. For the purposes of this invention, the words “network”, “networked”, and “networking” are understood to encompass wired Ethernet, fiber optic connections, wireless connections including any of the various 802.11 standards, cellular WAN infrastructures such as 3G, 4G/LTE, or 5G networks, Bluetooth®, Bluetooth® Low Energy (BLE) or Zigbee® communication links, or any other method by which one electronic device is capable of communicating with another. In some embodiments, elements of the networked portion of the invention may be implemented over a Virtual Private Network (VPN).

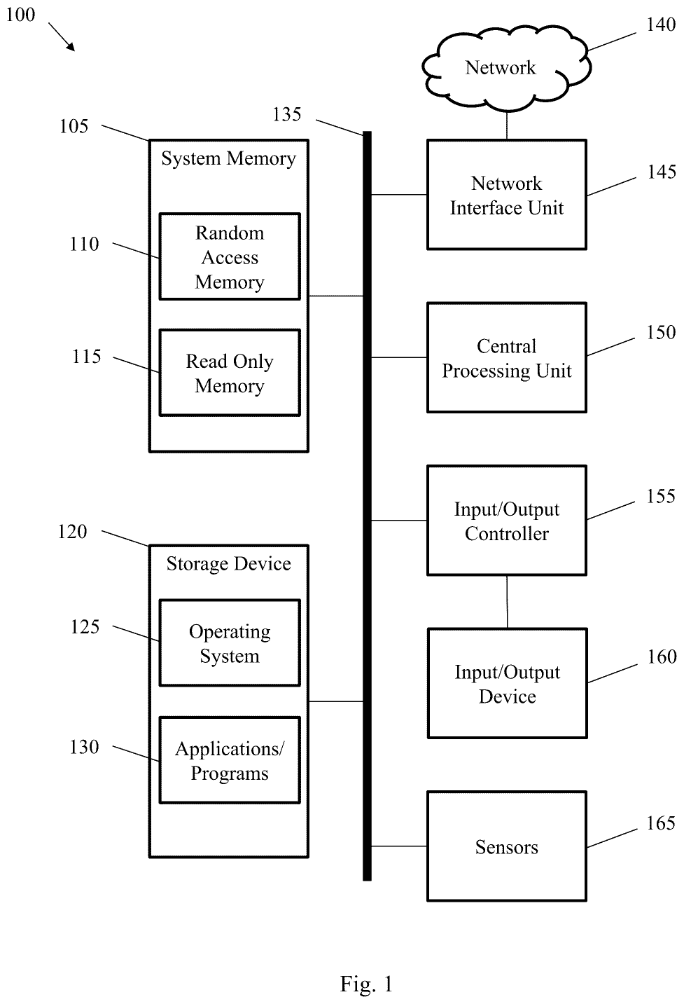

FIG. 1 and the following discussion are intended to provide a brief, general description of a suitable computing environment in which the invention may be implemented. While the invention is described above in the general context of program modules that execute in conjunction with an application program that runs on an operating system on a computer, those skilled in the art will recognize that the invention may also be implemented in combination with other program modules.

Generally, program modules include routines, programs, components, data structures, and other types of structures that perform particular tasks or implement particular abstract data types. Moreover, those skilled in the art will appreciate that the invention may be practiced with other computer system configurations, including hand-held devices, multiprocessor systems, microprocessor-based or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote memory storage devices.

FIG. 1 depicts an illustrative computer architecture for a computer 100 for practicing the various embodiments of the invention. The computer architecture shown in FIG. 1 illustrates a conventional personal computer, including a central processing unit 150 (“CPU”), a system memory 105, including a random access memory 110 (“RAM”) and a read-only memory (“ROM”) 115, and a system bus 135 that couples the system memory 105 to the CPU 150. A basic input/output system containing the basic routines that help to transfer information between elements within the computer, such as during startup, is stored in the ROM 115. The computer 100 further includes a storage device 120 for storing an operating system 125, application/program 130, and data.

The storage device 120 is connected to the CPU 150 through a storage controller (not shown) connected to the bus 135. The storage device 120 and its associated computer-readable media provide non-volatile storage for the computer 100. Although the description of computer-readable media contained herein refers to a storage device, such as a hard disk or CD-ROM drive, it should be appreciated by those skilled in the art that computer-readable media can be any available media that can be accessed by the computer 100.

By way of example, and not to be limiting, computer-readable media may comprise computer storage media. Computer storage media includes volatile and non-volatile, removable and non-removable media implemented in any method or technology for storage of information such as computer-readable instructions, data structures, program modules or other data. Computer storage media includes, but is not limited to, RAM, ROM, EPROM, EEPROM, flash memory or other solid state memory technology, CD-ROM, DVD, or other optical storage, magnetic cassettes, magnetic tape, magnetic disk storage or other magnetic storage devices, or any other medium which can be used to store the desired information and which can be accessed by the computer.

According to various embodiments of the invention, the computer 100 may operate in a networked environment using logical connections to remote computers through a network 140, such as TCP/IP network such as the Internet or an intranet. The computer 100 may connect to the network 140 through a network interface unit 145 connected to the bus 135. It should be appreciated that the network interface unit 145 may also be utilized to connect to other types of networks and remote computer systems.

The computer 100 may also include an input/output controller 155 for receiving and processing input from a number of input/output devices 160, including a keyboard, a mouse, a touchscreen, a camera, a microphone, a controller, a joystick, or other type of input device. Similarly, the input/output controller 155 may provide output to a display screen, a printer, a speaker, or other type of output device. The computer 100 can connect to the input/output device 160 via a wired connection including, but not limited to, fiber optic, Ethernet, or copper wire or wireless means including, but not limited to, Wi-Fi, Bluetooth, Near-Field Communication (NFC), infrared, or other suitable wired or wireless connections.

As mentioned briefly above, a number of program modules and data files may be stored in the storage device 120 and/or RAM 110 of the computer 100, including an operating system 125 suitable for controlling the operation of a networked computer. The storage device 120 and RAM 110 may also store one or more applications/programs 130. In particular, the storage device 120 and RAM 110 may store an application/program 130 for providing a variety of functionalities to a user. For instance, the application/program 130 may comprise many types of programs such as a word processing application, a spreadsheet application, a desktop publishing application, a database application, a gaming application, internet browsing application, electronic mail application, messaging application, and the like. According to an embodiment of the present invention, the application/program 130 comprises a multiple functionality software application for providing word processing functionality, slide presentation functionality, spreadsheet functionality, database functionality and the like.

The computer 100 in some embodiments can include a variety of sensors 165 for monitoring the environment surrounding and the environment internal to the computer 100. These sensors 165 can include a Global Positioning System (GPS) sensor, a photosensitive sensor, a gyroscope, a magnetometer, thermometer, a proximity sensor, an accelerometer, a microphone, biometric sensor, barometer, humidity sensor, radiation sensor, or any other suitable sensor.

Ising machines can map and solve optimization problems in Ising formulation. Such problems are also expressed in an equivalent quadratic unconstrained binary optimization (QUBO) formulation. In early stages of Ising machines, there is still an emphasis on demonstrating the underlying physical principle. Because of this, near-neighbor coupling is a common theme among designs, since coupling a large number of spins is technically very challenging. Moreover, since existing Ising machines largely avoid all-to-all connections, in newer efforts, designers understandably feel justified in also avoiding the challenge. As shown herein, a careful analysis will make it obvious that the problems it creates are numerous and significant.

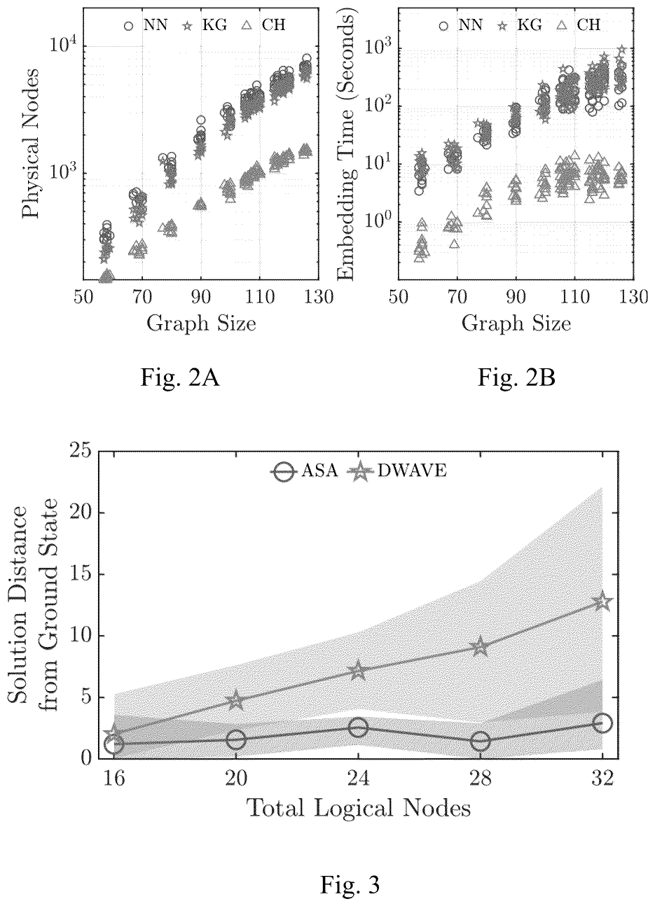

The first challenge is time cost in preprocessing. When an Ising machine provides a limited connectivity scheme, an arbitrary problem will need to go through an embedding process before it can be mapped to the hardware. FIG. 2A and FIG. 2B show the effect of this process on several machines that provide connections only to nearest neighbors (NN)-King's graph (KG), and Chimera (CH). Although nominally having between 2000 and 30,000 spins, these machines are in effect limited to 127 logical spins. At such a problem size, a conventional simulated annealing code can obtain very good results in under 5 ms. In contrast, the embedding process takes 1000× to 200,000× longer just for pre-processing. The NN results shown in FIG. 2A and FIG. 2B are for a 20,000-spin Nearest Neighbor, and KG is a 30,927-spin KingsGraph. CH is a 2048-spin Chimera.

The second challenge is cost in hardware resources. Even if the embedding time is ignored, the number of physical spins needed grows fundamentally at O(N²) for any fixed-degree topology. This is because a generic QUBO problem with N binary variables is specified with O(N²) control parameters. In an Ising machine with a fixed degree topology, to get O(N²) programmable edges necessarily means it has O(N²) physical spins. As a result, an Ising machine with fixed-degree couplings merely provides a large number of nominal spins. This is shown in a concrete example in Table 1.

TABLE 1

| | 17 pins | 4 u |
|---|---|---|
| All-to-all | 1000 | 500,000 |
| Mesh | 250,000 | 500,000 |
| Chimera (K_{4, 4}) | 125,000 | 500,000 |

Table 1 is an Example showing a lower-bound in the number of spins and coupling units (cu).

Existing Ising Machines may be divided into three categories based on the technology used for their design: Quantum, Optical, and Electronic annealers.

The latest Quantum Ising annealer manufactured by D-wave can support up to 2000 qubits. The qubits are coupled to form a chimera graph. As a result of local coupling, the D-wave machine can only map up to 64 nodes all to all connected graph. These annealers are also susceptible to noise, necessitating a cryogenic operating condition that consumes much power (25KW for the D-Wave 2000q).

The Most popular optical-based Ising machine is the Coherent Ising Machine (CIM). It uses an optical parametric oscillator (OPO) to generate and manipulate a signal to represent one spin. Unlike D-Wave, CIM nodes are all-to-all coupled. The machine has two components; an optical cavity built using kilometers of fiber, and an auxiliary computer to implement coupling between nodes. Every pulse's amplitude and phase in the optical cavity are detected, and its interaction with all other pulses is calculated using an auxiliary computer (FPGA). This computation is then used to modulate new pulses that are injected back into the optical cavity. Strictly speaking, the current implementation is a nature-simulation hybrid Ising machine. Thus, beyond the challenge of constructing the cavity, CIM also requires a significant supporting structure that involves fast conversions between optical and electrical signals.

The operating principle of CIM can be viewed as a Kuramoto model (see Takeda, et al., Quantum Science and Technology, 2017), so in theory, the one can achieve a similar goal using other oscillators. This led to the design of electronic Oscillator-based Ising Machines (OIM). These systems use LC tanks for spins and (programmable) resistors as coupling units. However, inductors are often a source of practical challenges for on-chip integration. They are area intensive and have undesirable parasitics with reduced quality and increased phase noise, which poses practical challenges in maintaining frequency uniformity and phase synchronicity between thousands of on-chip oscillators.

The disclosed BRIM design, discussed in more detail above, is an electronic design with resistive coupling, in which the Ising spin is implemented as capacitor voltage controlled by a feedback circuit, making it bistable. Since it uses voltage (as opposed to phase) to represent spin, it enables a straightforward interface to additional architectural support for computational tasks.

Researchers have also designed different chips to accelerate simulated annealing, or a variant of the classic algorithm. In these designs, the spins are virtual, in that they are bits in memory and manipulated by an algorithm (simulated annealing). These machines are specially built to accelerate that algorithm. Hence this design is referred to as an Accelerated Simulated Annealer (ASA). These are fundamentally different from regular Ising machines as they follow a particular algorithm, whereas regular Ising machines are guided by physical laws themselves.

Consider a fully-connected problem with 1000 spin variables and thus around 500,000 coupling coefficients. In a nearest-neighbor (mesh) system, one can calculate a very loose lower bound of the size of the system that can map the problem. This can be done by assuming every coupler is used to express a program coefficient—this is optimistic because in reality, many of the couplers will simply connect nearby spins to form a logical spin. Even in this case, an array of 500×500 is necessary to have enough couplers for the coupling coefficients. The nearest-neighbor architecture requires 250,000 spins just to get enough coupling units, which is what is truly needed. While the cost of 250,000 spin units is real and substantial, the notion that the system possesses that many nominal spins is meaningless. In fact, instead of arbitrarily referring to the problem as having 1000 spin variables, it could simply be described as having half a million coupling coefficients. In that case, the most resource-efficient system is an all-to-all architecture, with only 1000 spins needed.

Another challenge is cost in solution quality. Fixed-degree topologies are in fact wasteful in resources needed to provide the same computational capacity. Worse still, the process of mapping a single logical spin to a large number of physical spins creates subtle problems that result in an additional problem: poor solution quality. The present disclosure will first show an empirical observation and then explain that the loss in solution quality is fundamental.

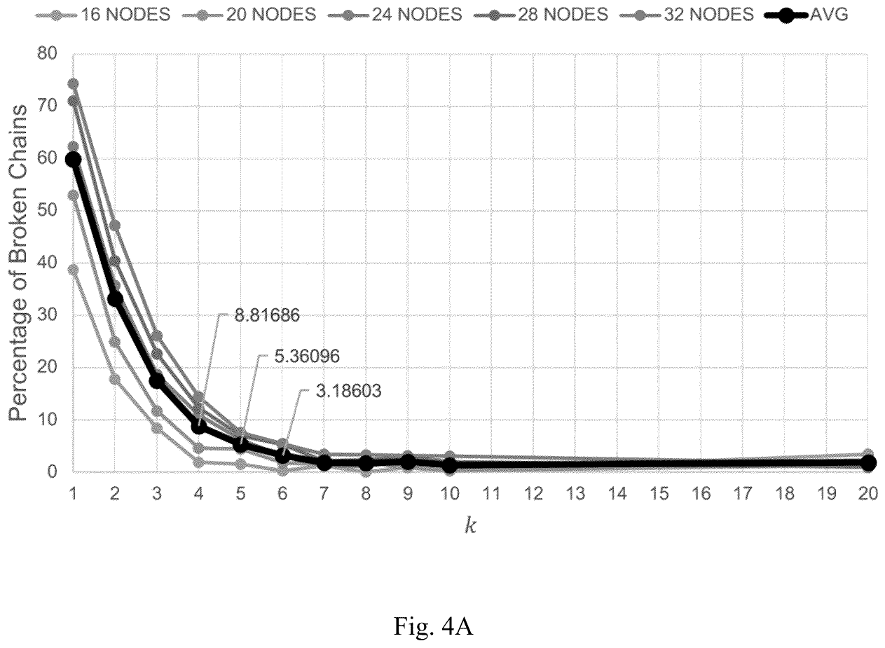

Two example machines using fixed-degree coupling are first considered: D-Wave's 2000Q which uses a Chimera graph and an accelerated simulated annealer (ASA) that uses a King's Graph. FIG. 3 shows the two machines solving small graphs of up to 32 logical spins. At this scale, the phase space can be quickly enumerated and the definitive ground state can be obtained. Simulated annealing (and a simulated version of the disclosed BRIM) can achieve ground state with very high probabilities with 20 us annealing time. Yet as FIG. 3 shows, both near-neighbor machines have trouble achieving ground state with the same annealing time. With further study, it is shown that the reason for the poor solution quality is fundamental.

In an embedded problem, a logical spin from the original problem is represented as a (large) chain of physical spins that are strongly coupled together so that (hopefully) they have the same polarity. This is done by assigning a coupling strength of k (assuming the problem coefficients are already normalized to 1). Note that increasing k only reduces the chance a chain is “broken” (physical spins within it have both polarities) but cannot guarantee the absence of broken chains.

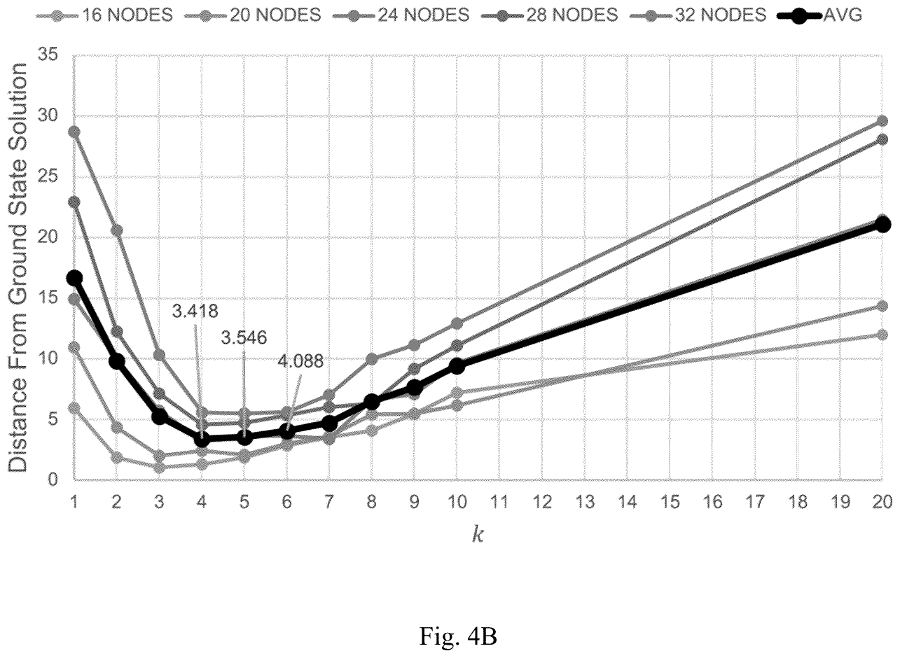

To provide a more concrete illustration of the problem, consider a set of very small programs of 16 to 32 logical spins, converted through minor embedding into a physical layout with Chimera-couplings. The transformed energy landscape may then be navigated using a state-of-the-art simulated annealing solver (Isakov, et al., Computer Physics Communications, 2015). FIG. 4A shows the percentage of chains broken when varying the coupling strength k. Note that because simulated annealing is used, the findings are only about the inherent properties of the energy landscape itself. Machine imperfection is not even a factor in this idealized experiment and will only add to the problem in the real world.

From FIG. 4A and FIG. 4B, it is shown that at the end of the annealing schedule, between 40% and 75% of all chains are broken. Note that even if only one chain is broken, the original solution is illegal. Stated differently, the embedded problem represents a completely different phase space, vastly bigger than that of the original phase space (2^{O(N\hat{ }2)} vs 2^{O(N)}). In this new space, almost all of the phase points (2^{O(N\hat{ }2)}−2^{O(N)}) technically represent illegal solutions. It is no wonder that the annealer is exceedingly unlikely to find a legal solution.

One might think that sampling an illegal solution is not a problem or that in any case, increasing k can easily mitigate the problem. Both are true, but only to some extent. First, obtaining an illegal solution is not an issue per se. It is not difficult to transform a raw solution into a legal solution of the original problem. A common practice is to use a majority vote to decide on the chain's overall polarity. Increasing k clearly has an effect on reducing the percentage of broken chains as shown in FIG. 4A. However, examining the end result of the solution quality (FIG. 4B), it is shown that increasing k initially helps, but beyond a certain point it becomes counterproductive. Keep in mind, these graphs are exceedingly small and their entire phase space can be quickly enumerated. A conventional solver always finds a ground-state solution very quickly.

Considering a concrete example, it is shown that the observations shown in the figure are quite understandable. With a 32-node graph g (representing a 32-spin Ising formulation), for example, the size of its phase space is 2³¹. Through minor embedding, the transformed graph gₑ has 320 nodes. Only 2³² phase points in ge are legal, i.e., they correspond directly back to those of g. In other words, for every legal phase point, there are 2²⁸⁸ illegal ones. When a solver explores the phase space ge and obtains a solution (call it [symbol] ), it is entirely understandable that it is an illegal solution despite the fact that illegal phase points have a higher energy in general: the numerical odds (1 in 2²⁸⁸) are simply overwhelming.

When converting into a legal solution with a majority vote, one essentially substitutes [symbol] with a legal solution [symbol] ′). The merit of [symbol] ′ is that it is the closest legal solution (in Hamming distance in the enlarged phase space of gₑ) to [symbol] . The implied assumption is that if [symbol] is a good solution (low energy), changing a few spins into [symbol] ′ will still provide a reasonably good solution. But [symbol] ′ being the closest legal solution does not imply it is close in some absolute sense: all 2²⁸⁸ phase points share one legal phase point as the closest legal phase point. Most of them will have a non-trivial distance from that legal phase point. In general, the greater the distance, the less correlation of energy there is between [symbol] ′ and [symbol] . As a concrete example, in one 32-node graph with k=1, the majority-vote-derived solution [symbol] ′ has a Hamming distance 112 from the original solution [symbol] .

This problem can be mitigated to some extent. Using a larger k, for instance, has the effect of increasing the penalty for illegal solutions. However, this is again not without cost. Increasing k beyond a certain point will be counterproductive, as that would put too much emphasis on not breaking any chain and not enough emphasis on the quality difference between different legal solutions. Empirically, in these test problems, it is found that an optimal value of k=4. Given a finite dynamic range of coupling coefficient in a realistic analog hardware, a large k value simply takes away the usable range to express the actual problem. In the disclosed example, k=4 has the effect of reserving 2 bits for the use of lowering the impact of broken chains. Unfortunately, as the graph increases in size, the optimal value of k increases as can be seen in the figure. This means that in real-world problems with thousands of spins, more of the system's dynamic range will be needed to program k.

As shown above, the embedding process not only changes the number of spins required to map the problem and demands significant preprocessing, it also has a significant impact on the solution quality because it forces a search on a proxy energy landscape rather than the original problem's energy landscape. All in all, near-neighbor coupling creates a host of genuine problems that are often ignored in literature. Every indication suggests that it is not a solution to the challenge of increasing a machine's problem-solving capacity. While it lowers the barrier to building proof-of-concept prototypes, machines in the next stage need to efficiently support all-to-all coupling.

One apparent alternative to providing physical all-to-all coupling is providing emulated coupling. In coherent Ising machines (CIM) (see Inagaki, et al., Science, 2016; Yamamoto, et al., npj Quantum Information, 2017; McMahon, et al., Science, 2016; Takata, et al., Scientific Reports, 2016; and Böhm, et al., Nature Communications, 2019), this is achieved by measuring a pulse i, numerically computing the coupling effect to another pulse j, and subsequently injecting a corresponding signal that represents the computed value back into the dynamical system. While this approach also facilitates building a proof-of-concept prototype, it creates problems for high-performance systems, as the computation delay and energy both limit the overall speed and energy efficiency of the system.

A recent comparison between a computational solution, Simulated Bifurcation (SB) and CIM is revealing (see Tatsumura, et al, 2019 29th International Conference on Field Programmable Logic and Applications (FPL), 2019).

In SB, the entire dynamical system is simulated with computation. For every round of interaction O(N²) multiply-accumulate (MAC) operations are needed for both SB and CIM. While one expects some advantage for CIM as it contains some hardware whereas SB is purely a simulator, it turns out SB is much faster. For a commonly used problem (K2000), to reach a certain solution quality, SB needed 25 rounds/steps, while CIM needs more than 150 rounds. In other words: the software-based SB is both faster and more energy efficient than a hybrid Ising machine. This example clearly casts doubt on the utility of von Neumann-emulated coupling in Ising machines.

Finally, a more recent incarnation of CIM manages to reach an impressive 100,000 spins due in part to the incorporation of a piezo-based fiber stretcher to help achieve a stable phase relationship among such a large number of pulses in the 5-km fiber. Upon a closer inspection of the computational substrate used to perform the so-called digitally assisted mutual interaction, the issue with such an approach is clear. First, the entire machine is constructed for a special type of graph where the weights of couplings are only 1 or −1. Despite supporting only low bit-precision calculations, the von Neumann computing took 54 top-of-the-line FPGAs (XCVU13P-2FHGB2104I). Together, just the computational elements consume about 6 kW (see Honjo, et al., Science Advances, 2021).

Intuitively, nature-based computational systems leverage the computation done by nature to achieve extraordinary speed and energy efficiency. Such advantages may disappear completely or would be significantly diminished if von Neumann computing is relied upon to emulate nature.

Though existing Ising machines seem to offer a non-trivial number of spins, they fall into two categories, neither of which represents a promising future:

(1) Architectures with near-neighbor coupling, which create a larger number of nominal spins. There is no indication that these genuinely improve the machine's problem-solving capacity (effective spins). Instead, they create an extremely expensive preprocessing demand, use hardware resources poorly, and fundamentally lowers the solution quality. Each of these three technical problems is extremely challenging to address and possibly has no solution.

(2) Emulated all-to-all coupling, which creates an enormous amount of traditional (von Neumann) computing demand and its concomitant energy overhead. At the moment, the computing demand and thus energy required is far worse than traditional solvers.

Therefore, the best (if not the only) approach is to deliver hardware coupling mechanisms so efficient (in area and energy) that genuine all-to-all coupling is feasible at the hardware level. Only then can the dynamical system leverage nature to perform certain types of tasks orders-of-magnitude faster and more energy efficiently than conventional von Neumann solvers. Every indication of preliminary research shows that this is doable. The focus of the disclosed hardware system is exactly to deliver such hardware—at scale. In the vast majority of cases, there are no disadvantages to the disclosed global all-to-all architecture over less demanding ones. In a few unlikely situations, current near-neighbor topologies may be worth consideration.

Given a technology of spin, it may be technically impossible to couple many nodes together. (Such a technology would not be a promising one to explore.) Another example of a potentially suitable use case for a near-neighbor topology is where a custom architecture is being built for fixed problems whose connection matrix is very sparse. In those cases, the disclosed technology can also be used with a sparse-coupling architecture, resulting in a correspondingly smaller system.

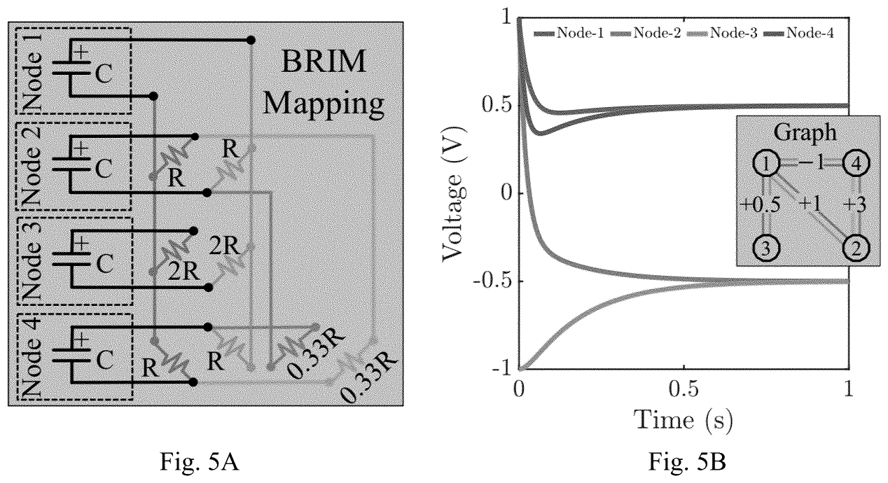

It is intuited that in the Ising model, when two nodes (i and j) are strongly and positively coupled (Jᵢⱼ is large and positive), their spins are likely to be parallel (σᵢ=σⱼ). Similarly, a strong negative coupling will likely lead to anti-parallel spins (σᵢ=−σⱼ), while a |Jᵢⱼ|≈0 suggests that the two spins are more likely to be independent. This behavior can be easily mimicked with resistively coupled capacitors, where the spin of a node is represented by the polarity of the voltage vᵢ across the capacitor Cᵢ while the coupling between nodes is through resistors Rᵢⱼ=R_{c}/|Jᵢⱼ|, where R_{c} is a scaling constant equal to the minimum resistance achievable (or allowed) in a certain technology. The sign of coupling can be achieved by connecting either the same or opposite polarity in the corresponding capacitors. FIG. 5A shows a simple 4-node system mapped from a Weighted Max-Cut problem with the labeled edge weights. After the capacitor voltages are randomly initialized to ±1, the system indeed seeks equilibrium as shown in FIG. 5B, at which time the nodal polarities (i.e., spins) separate the nodes into {1,4} and {2,3} representing a correct solution to the Max-Cut problem. A six-node discrete-component prototype is shown in Afoakwa, et al., International Symposium on High-Performance Computer Architecture (2021) for more realism.

Bistability: The oversimplified design confirms the intuition but is far from a robust design. For example, in the presence of a trivial equilibrium state (vᵢ=0), frustrations (i.e., more than one equilibrium with the same energy is present), or leakage on the capacitors, the equilibrium voltages can be 0 or just too low for reliable readout.

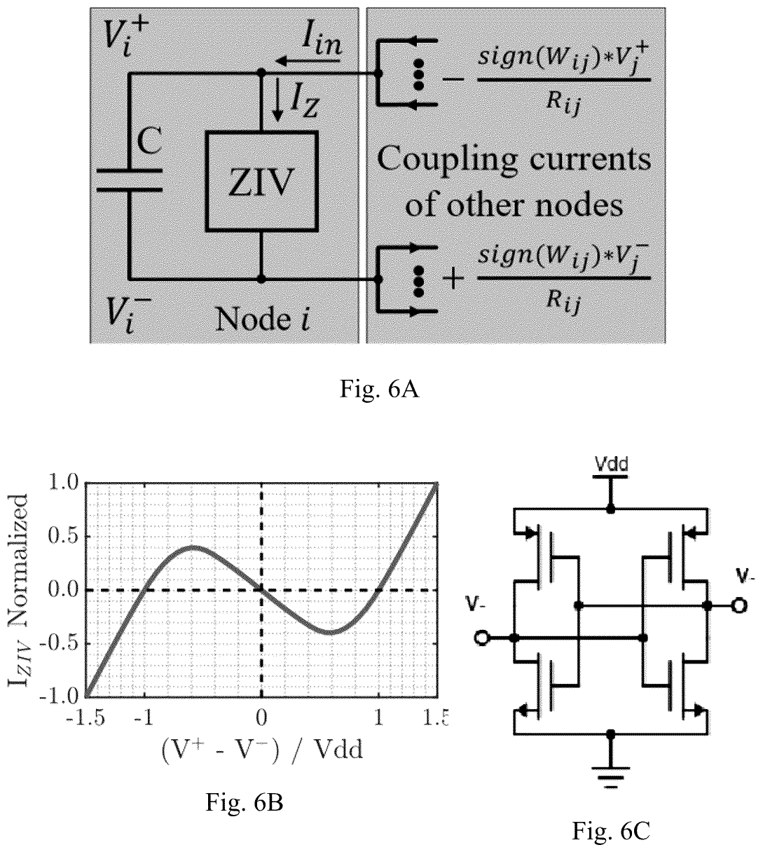

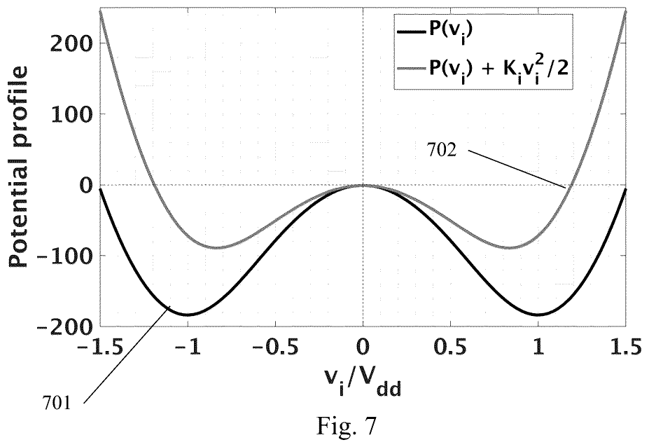

A local feedback circuit is therefore needed to keep the nodes away from 0V and closer to power rails—i.e., make nodes bistable. Such active feedback may be achieved in some embodiments by a ZIV diode, whose name comes from its slanted “Z” shaped IV-curve, g_{ZIV}(vᵢ), as shown in FIG. 6B). An example ZIV diode implementation suitable for CMOS integration is shown in FIG. 6C. While details of the design can be found in Afoakwa, et al., International Symposium on High-Performance Computer Architecture (2021), the important thing to note is that the resulting dynamical system (a node of which is shown in FIG. 6A) is governed by Equation 5 below with a Lyapunov function show in Equation 6,

$$\frac{d {v}_{i}}{d t} = \frac{1}{{R}_{c} C} [ {\sum }_{j \neq i} {J}_{i j} {v}_{j} - {\sum }_{j \neq i} ( \vert {J}_{i j} \vert {v}_{i} - {R}_{c} * {g}_{ZIV} ( {v}_{i} ) ) ] \qquad Equation 5$$

$$H ( v ) = \frac{1}{{R}_{c} C} [ - {\sum }_{i < j} {J}_{ij} {v}_{i} {v}_{j} + {\sum }_{i} ( \frac{{K}_{i} {v}_{i}^{2}}{2} + {R}_{c} * P ( {v}_{i} ) ) ] ; {K}_{i} = {\sum }_{j \neq i} \vert {J}_{ij} \vert \qquad Equation 6$$

where P(vᵢ) is obtained by integrating g_{ZIV}(vᵢ) over vᵢ. It is important to note that the particular IV characteristic of a ZIV diode will give P(v) a double-well profile (black curve 701 in FIG. 7) with two stable equilibrium points at voltages corresponding to two non-trivial zero-crossings of the IV curve (e.g., vᵢ=±V_{dd}) and a saddle point at vᵢ=0V. Given the double-well profile of P(v), the state of a stable solution will include voltages at (or at least very close to) these equilibria (e.g., ±V_{dd}). However, the Kᵢvᵢ²/2 term in the second summation of Equation 6 above might affect a double-well profile as shown by red curve 702 in FIG. 7 (i.e., it may cause potential wells to merge into a trivial single-well profile representing a lossy dynamical system whose equilibrium state vᵢ=0 does not minimize the Ising term). This situation can be prevented by choosing a proper scaling resistor R_{c} to guarantee a double-well profile (or bi-stability of nodal voltages). From Equation 6 it is apparent why BRIM tends to seek (local) minima of the objective term (−Σ_{i<j}Jᵢⱼvⱼvᵢ). As discussed in Afoakwa, et al, random spin flips also help to better explore the energy landscape.

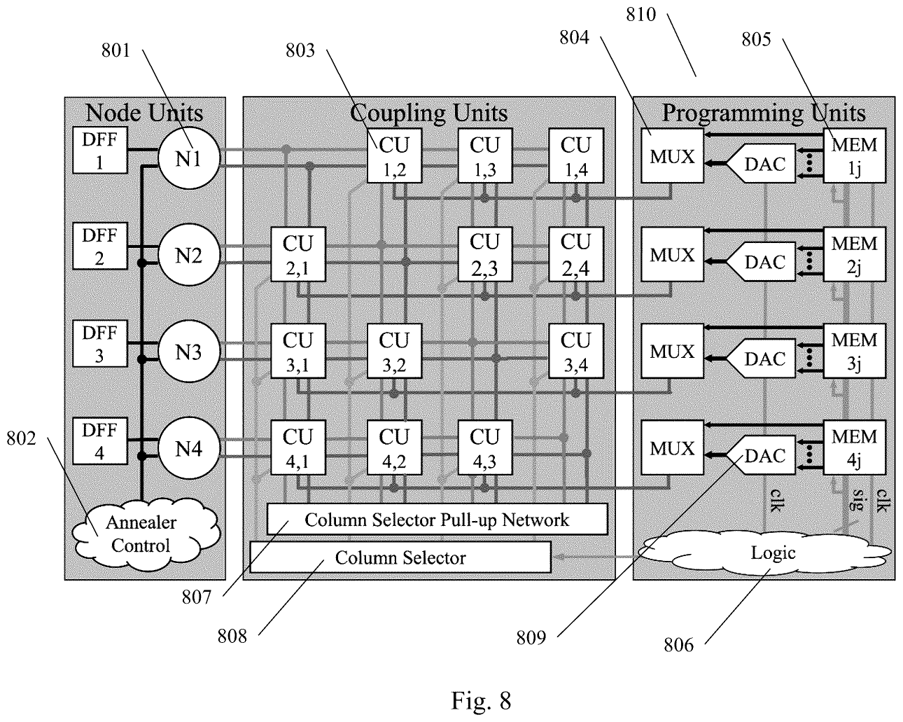

A more complete system design is illustrated in FIG. 8 and comprises bistable nodes 801, a digital interface, coupling units 802, programming units to configure coupling weights 810, including: memory, 805 multiplexers 804, and DACs 809, and annealing and randomized spin-flip controls 802. Each CU 803 comprises a PMOS-based resistor whose equivalent channel resistance is programmed by the row-level DAC 809 by applying appropriate gate voltage that is stored on and held by the PMOS gate capacitance.

Coupling unit (CU): With an array of BRIM nodes, one has the flexibility to couple them in any desired topology. As discussed quantitatively above, an all-to-all coupling is computationally more useful and is thus the better choice. The coupling in BRIM is achieved through an array of CUs each containing several programmable/variable resistors.

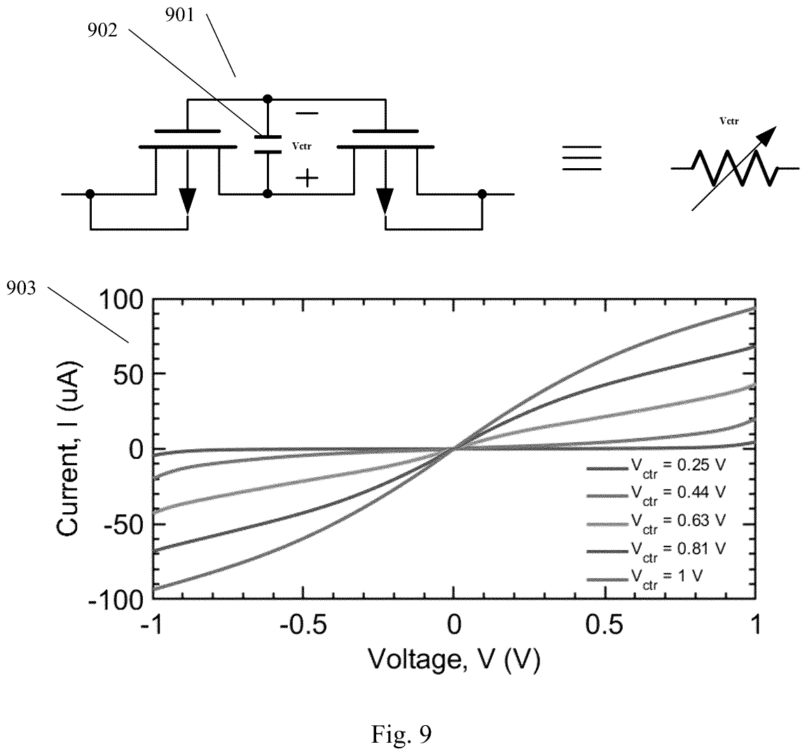

Although coupling resistors may be implemented in standard CMOS using a single MOSFET biased in a triode region, the linearity is expected to be unsatisfactory due to the large voltages applied (e.g., the largest anticipated voltage across the programmable resistors would span rail-to-rail). For this reason, we a double-PMOS-based resistor is used (referred to herein as R-PMOS). As illustrated at the top of FIG. 9, an R-PMOS resistor 901 includes two identical PMOS devices connected in series with common gate electrode. The resistance of the R-PMOS can be programmed by setting the gate voltage (V_{ctr}) to an appropriate value. V_{ctr} for each R-PMOS is set by a row-level Digital-to-Analog converter (DAC) (e.g. 809) and is maintained on an MiM capacitor or a MOSCAP 902 (internal to the CU) during the machine's operation. The R-PMOS manifests a symmetric resistance with respect to the polarity of the voltage applied across its terminals. The simulated I-V characteristics of PMOS in 45 nm CMOS technology is shown in graph 903 of FIG. 9, exhibiting an improved linearity as compared to a single PMOS in triode.

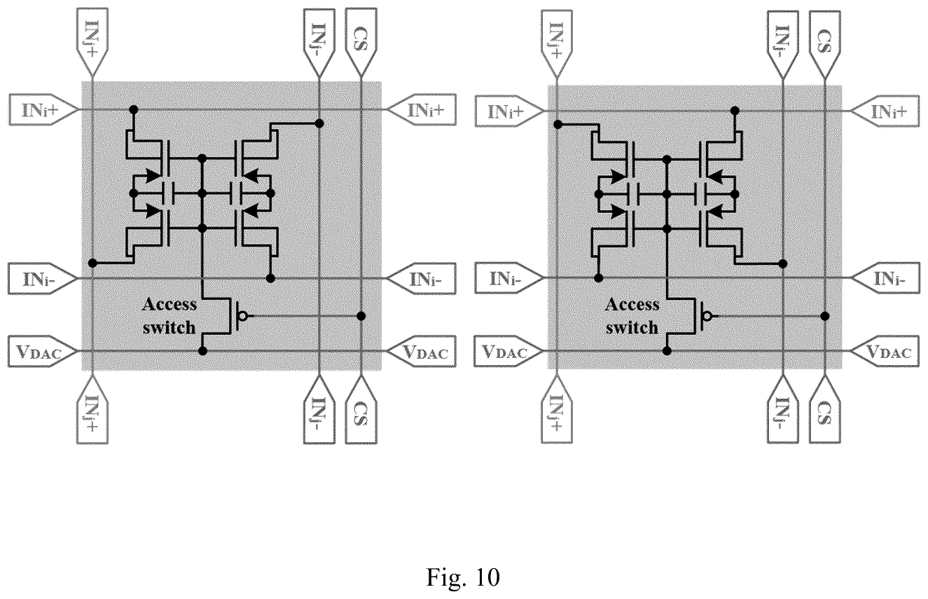

In the disclosed system, the coupling is bidirectional and, in principle, could be achieved by using a total of N(N−1)/2 CUs. However, to achieve bipolar coupling between any two nodal capacitors (both positive/parallel and negative/anti-parallel coupling) and to accommodate fully-differential operation, each CU in the N(N−1)/2 array would require four R-PMOS resistors (a pair for each coupling polarity choice), a 2×2 crossbar switch to select between parallel or anti-parallel connection as well as a memory cell and logic gates to store and control the state of the crossbar switch. A more area efficient design which alleviates the need for the crossbar switch and local memory cell is to divide each bidirectional CU of the N(N−1)/2 design into two smaller units each handling only one type of polarity. Although this approach results in a total of N(N-1) CUs (as shown in FIG. 8), the split units are substantially smaller in area (more than 2 times) than the bidirectional CUs of the N(N−1)/2 design. For example, the CUs belonging to the upper triangle portion of the array in FIG. 8 (i.e., CUᵢⱼ units where i<j) are dedicated to parallel coupling while those belonging to the lower triangle are dedicated to anti-parallel coupling. For illustration purposes, if nodes Nᵢ and Nⱼ are to be coupled in parallel with resistance equal to Rᵢⱼ=R_{c}/Jᵢⱼ| then a pair of PMOS resistors in CUᵢⱼ are programmed to Rᵢⱼ while the R-PMOS in CUⱼᵢ are set to a sufficiently large value as to ensure no negative (or anti-parallel) coupling between the two nodes. As seen in FIG. 10, each CU has two programmable resistors, two capacitors (one of each RPMOS) to store the control voltage V_{ctr}, and a column select access switch to connect gates of the R-PMOS to the row-level DAC for programming.

Both the initial nodal values and the coupling resistances are programmable. To the right of the coupling unit array in FIG. 8 is the array of programming units 810. The digital memory 805 (e.g., an SRAM) stores the coupling coefficients to be loaded to the DAC array as well as the control signals for the MUX array. In the depicted example, the programming process is performed in a time-interleaved fashion (one column at a time) with the help of a column selector and pull-up network as shown below the coupling units in FIG. 8. During the programming phase, the column selector selects a particular column (e.g., j^{th} column) by connecting its chip select (CS) line to 0V, which turns on all access switches connecting the gates of RPMOS resistors within the j^{th} column to the row-level programming units. At the same time, the pull-up logic holds the terminal voltages of all the R-PMOS's in the j^{th} column to V_{DD} through the vertical interconnect lines IN and IN. Depending on the coupling polarity, the MUX in each row (e.g., i^{th} row) determines if the intersected CUᵢⱼ is to be activated or not. For example, if CUᵢⱼ is to be activated, its R-PMOS gates are charged to the voltage provided by the DAC, otherwise, they are charged to V_{DD} provided by the i^{th} MUX unit, which turns off its R-PMOS resistors setting their resistance to a very high, practically infinite value. Note that CUs which are symmetrical with respect to the main diagonal of the CU array are either both inactivated or only one is activated depending on the polarity of the coupling. For example, if the coupling coefficient Jᵢⱼ is negative, the resistances in CUᵢⱼ should be set to infinity and the resistances of CUⱼᵢ should be set to

$$\frac{{R}_{c}}{\vert {J}_{i j} \vert} ,$$

where R_{c} is the minimum achievable resistance of the R-PMOS. The activation of CUᵢⱼ VS. CUⱼᵢ is accomplished by the MUX units in iₜₕ and jₜₕ rows. Once the programming of all columns is completed, the row level DAC's and MUX units are shut down to save power. Similar to DRAM cells, we anticipate that R-PMOS will exhibit gate leakage currents that, if not refreshed, will discharge the R-PMOS capacitances over time (order of milliseconds) changing the pre-set resistance values. For this reason, in some embodiments, thick-oxide PMOS devices may be used to implement R-PMOS, which exhibit orders of magnitude lower leakage than thin oxide (low-voltage) devices. It is also anticipated that the programming steps will need to be repeated several times during operation to “refresh” the coupling values to the desired value.

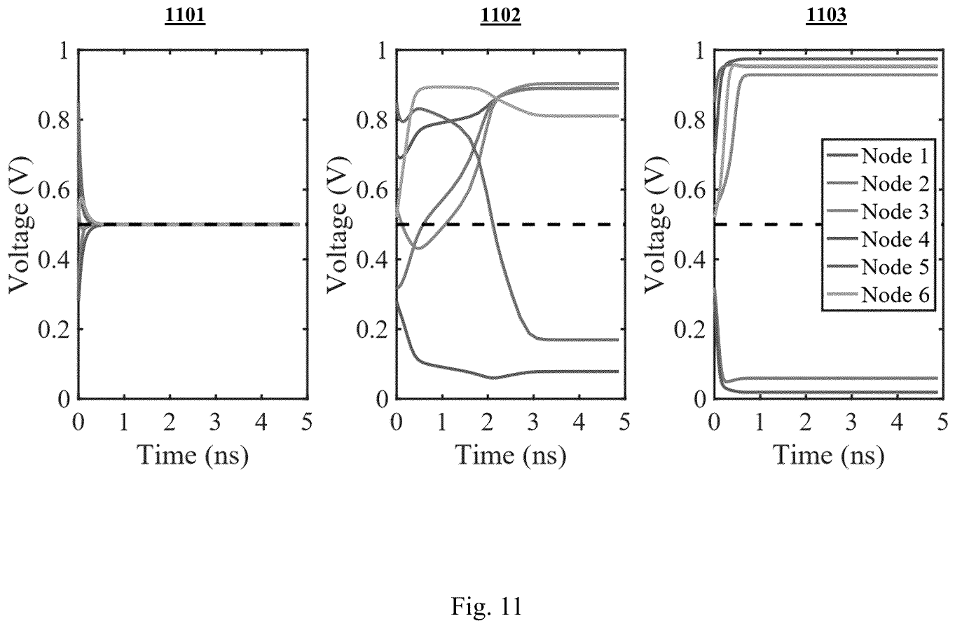

It is apparent from Equation 6 and FIG. 7 that there should be a balance between the strength of the ZIV diodes' currents and the coupling currents. As depicted in FIG. 11, if the ZIV diodes are too weak, (graph 1101) the overall system degenerates to a passive RC network, and all the nodal voltages might decay to zero. On the other hand, if the ZIV diodes are too strong (graph 1103), they would cause the nodal voltages to bifurcate to the nearest vertex of the N-dimensional space largely disregarding the Ising term. Finding a proper balance (graph 1102) is non-trivial since it not only depends on R_{c} and the peak current in gziv but also on the machine's states. For this reason, an annealing approach is adopted in some embodiments where ZIV diodes' current contributions are gradually introduced over time (i.e., the ZIV diodes' strengths are dynamically adjusted). One approach to accomplish this is to regulate a duty-cycle (i.e., ZIV diodes are turned on and off during the machine's operation while the “on” time progressively becomes longer).

As pointed out above, the BRIM system can become stuck in a local maximum determined by the initial state. To allow the BRIM to escape a local maximum, in some embodiments a similar strategy may be used as that used in simulated annealing, which is to deploy perturbations in the state variables. For example, by performing a “spin flip” of select nodes (i.e., to change the spin to its opposite value), the system can be moved to a neighboring state in the global phase space. This allows the system to escape a basin of attraction (e.g. a local maximum) and explore new regions. In simulated annealing, the probability of such bit flips is a function of both the energy difference due to the bit flip and the current temperature. For implementation convenience, the temperature is used in some embodiments to decide the probability/frequency of spin flips. In some embodiments, the temperature follows an exponential annealing schedule. In other words, the frequency of spin flips decays exponentially. With this support, BRIM may be used similarly to other Ising machines: first, program the weights/coupling coefficients; then, select the annealing time; and finally, read out the state of the nodes after the completion of the annealing schedule. The annealing schedule for ZIV diodes and spin perturbations may be controlled either globally for all nodes or locally for each node individually.

There are several circuit non-idealities that might affect the coupling accuracy and dynamic range (DR), for example, inherent kT/C noise, non-linearity in the R-PMOS resistance, gate oxide leakage current, and charge injection from the CU's access switch. Disclosed below is a preliminary analysis of the DR and precision, but it should be noted that a more detailed analysis exploring the many degrees of freedom and relevant trade-offs is warranted.

### Preliminary DR and Accuracy Analysis

Assuming a CU area of 1 μm×1 μm in a 45 nm standard CMOS and a total capacitance seen at the gates of R-PMOS of 4fF (including the gate capacitance and additional 2fF Metal-insulator-metal, or MiM, capacitor per RPMOS), the expected kT/C noise is about 1m Vᵣₘₛ resulting in 0.1% and 0.38% error in the channel resistance of 60kΩ and 7MΩ, respectively. Since |Jᵢⱼ≈1/Rᵢⱼ, the DR of the coupling coefficients |Jᵢⱼ may be defined as a ratio of the upper bound on |Jᵢⱼ| corresponding to the smallest programmable resistance of R-PMOS (in this example CU in 45 nm, minimum Rᵢⱼ=60kΩ and the lower bound on |Jᵢⱼ|, which is defined by the error in the high-end resistance values. The relative error of R-PMOS resistance due to kT/C noise flattens at around 7MΩ to 0.38% resulting in a DR=20 log₁₀ (7M/(0.0038*60k))=89 dB or about 15 bits of resolution. On the other hand, the limitation on accuracy due to the kT/C noise is defined by the peak relative error of about 0.38% which translates into about 8 bits of effective resolution.

Another important issue to consider that may limit the overall coupling accuracy is the nonlinearity of the R-PMOS resistors. The preliminary non-linearity modeling in 45 nm CMOS indicates that the relative error (calculated as the ratio between the RMS deviation from the best fit line and the slope of the best fit line in graph 903 in FIG. 9) is equal to 1%, 3.4%, and 5% (with the corresponding effective resolution of 6.6, 4.9, and 4.3 bits) for the voltage range across the R-PMOS terminals of ±0.4V, ±0.6V, and ±0.8V, respectively. It is clear that the non-linearity, whose mitigation might require reducing voltage swings at the cost of reduced signal-to-noise ratio or increased circuit area and/or power, poses greater constraints on the achievable coupling precision than the error due to the inherent kT/C noise or charge injection.

It is also important to note that an extensive statistical analysis is needed to fully understand the extent of non-linearity effects on the BRIM's solution quality. More specifically, the type of the problems solved by Ising machines, including BRIM, are often such that the optimal solution is not guaranteed and only sub-optimal solutions are expected. Therefore, the true effect of the non-linearity on the solution quality could only be evaluated through a thorough analysis on a large set of graph problems.

### Quantized BRIM

Coupling between nodes is a key factor to build robust Ising machines because the problem to solve is directly embedded in it. Although the spin only takes two discrete values, the physical quantity that represents the spin can experience a large swing, which may pose many issues. For example, in resistively coupled Ising machines, this may cause a large variation in the coupling resistance, and very likely the machine is solving different problems at different times. Also, the trade-off between the size, power, and precise functionality of the building blocks limits the scalability.

In addition to reducing the maximum voltage swing across R-PMOS (e.g., by lowering power supply voltage), another approach to reducing the non-linearity effects is to adopt an alternative BRIM design (so-called Quantized BRIM, or QuBRIM, described in more detail below) where the voltage magnitudes across all R-PMOS are kept constant while the node-to node coupling becomes entirely current based. However, a QuBRIM design requires additional circuitry such as comparators/inverters and current-conveyors for current summation per node, thus scaling as O(N). In addition, since the coupling in QuBRIM is unidirectional (as opposed to BRIM's bidirectional coupling), each coupling would require two CU units, doubling the overall size of the CU array as compared to baseline BRIM.

The disclosed modified BRIM design (QuBRIM) is more area and power demanding than the baseline BRIM, but not only helps improve linearity and accuracy of the coupling coefficients but also creates a clear path towards an implementation of CMOS based Ising machines with multi-body interactions (e.g., cubic or higher order terms in Ising formula). The QuBRIM design is generated from the baseline BRIM by quantizing nodal variables (e.g., capacitor voltages vᵢ) to binary values (e.g., +1 or rail-to-rail) before they are coupled to capacitors of other nodes.

The resulting dynamical system is governed by Equation 7 below with a Lyapunov function shown in Equation 8, where Q(vᵢ) is a quantization function equal to +1 for vᵢ≥0 and −1, otherwise (or alternatively Q(vᵢ)=V_{dd} for vᵢ≥ V_{dd}/2 and 0V, otherwise).

$$\frac{d {v}_{i}}{d t} = \frac{1}{{R}_{c} C} [ {\sum }_{j \neq i} {J}_{ij} Q ( {v}_{j} ) - {R}_{c} {g}_{ZIV} ( {v}_{i} ) ] \qquad Equation 7$$

$$H ( v ) = \frac{α}{{R}_{c} C} ( - {\sum }_{i < j} {J}_{ij} ( Q ( {v}_{i} ) {v}_{j} + {v}_{i} Q ( {v}_{j} ) ) + {R}_{c} {\sum }_{i} P ( {v}_{i} ) ) \qquad Equation 8$$

Considered another way, the dynamic of QuBRIM can be described by the change of each nodal voltage caused by other nodes connected to it. Without loss of generality, the following focuses on the dynamic of one node to make the analysis neat, however, it can be easily extended to the whole system [v₁(t), v₂(t), . . . , v_{N}(t)]^{T}.

The dynamic of node i is expressed as

$$\frac{d {v}_{i}}{d t} = \frac{1}{C} {\sum }_{j \neq i} \frac{sgn ( {J}_{i j} ) \cdot Q ( {v}_{j} )}{{R}_{i j}} \qquad Equation 9$$

where the summation on the right side represents the currents flow to node i from other nodes with sgn(Jᵢⱼ) indicating the polarity of the coupling. However, note that these currents do not depend on vᵢ but only on the quantized voltage of other nodes, i.e., Q(vᵢ), where Q(vᵢ)=sgn (vᵢ). Recalling that Rᵢⱼ=R/J|ᵢⱼ|, the above equation becomes

$$\frac{d {v}_{i}}{d t} = \frac{1}{R C} {\sum }_{j \neq i} {J}_{i j} \cdot Q ( {v}_{j} ) = \frac{1}{τ} {\sum }_{j \neq i} {J}_{i j} \cdot Q ( {v}_{j} ) \qquad Equation 10$$

Given the set of differential equations above describing QuBRIM as a dynamic system, it can be shown that a Lyapunov function in the following form exists:

$$H ( v ) = - {\sum }_{i < j} {J}_{l j} \cdot Q ( {v}_{i} ) \cdot Q ( {v}_{j} ) \qquad Equation 11$$

Because the quantity Q(vᵢ) in Equation 11 only takes the values of {−1,+1} and can be used to directly represent the spin of the node j, the Lyapunov function in Equation 11 directly relates to the Ising Hamiltonian in Equation 2, i.e. by minimizing Lyapunov function in Equation 11, QuBRIM simultaneously seeks a minimum in the Ising Hamiltonian).

To show the ability for optimum-seeking of QuBRIM, a Lyapunov stability analysis is presented below, which states that if a function H(v) can be found such that

$$\frac{d H ( v )}{dt} = 0$$

at point v^{e}

$$\frac{d H ( v )}{dt} < 0$$

in the region around v^{e}, then v^{e} is the equilibrium point. In the disclosed case, the and equilibrium point corresponds to the solution to the equation set

$$\frac{d {v}_{i}}{dt} = 0 ;$$

i=1 . . . N.

Taking the time derivative of Equation 11, the following result is obtained after applying the chain rule:

$$\frac{d H ( v )}{d t} = {\sum }_{i} [ \frac{\partial H ( v )}{\partial Q ( {v}_{i} )} \cdot \frac{d Q ( {v}_{i} )}{d t} ] = {\sum }_{i} [ ( {\sum }_{j \neq i} {J}_{i j} \cdot Q ( {v}_{j} ) ) \cdot \frac{d Q ( {v}_{i} )}{d t} ] = - τ {\sum }_{i} [ \frac{d {v}_{i}}{d t} \cdot \frac{d Q ( {v}_{i} )}{d t} ] \qquad Equation 12$$

where the last line is the direct result of Equation 10. More importantly, one should notice that the product in the brackets is non-negative because vᵢ and Q(vᵢ) always change in the same direction. As a result, the time derivative of H(v) is non-positive, i.e. H(v) is a non-increasing function), so QuBRIM indeed satisfies the Lyapunov stability criterion. In other words, once the system enters a region, it will inevitably evolve towards lowering H(v) until it reaches the equilibrium point v^{e}. Consequently, minimizing H(v) is equal to minimizing the Ising formula in Equation 2.

However, the above analysis does not guarantee that the system will converge to a global minimum as it depends on the energy landscape and initial conditions. This is similar to other annealers: None has strong guarantees for reaching the ground state in a typical usage scenario (as opposed to ideal conditions) or in an efficient manner. For example, it is shown that simulated annealing can reach the ground state in a system with a finite phase space. However, the time it takes to do so may be longer than enumerating the space.

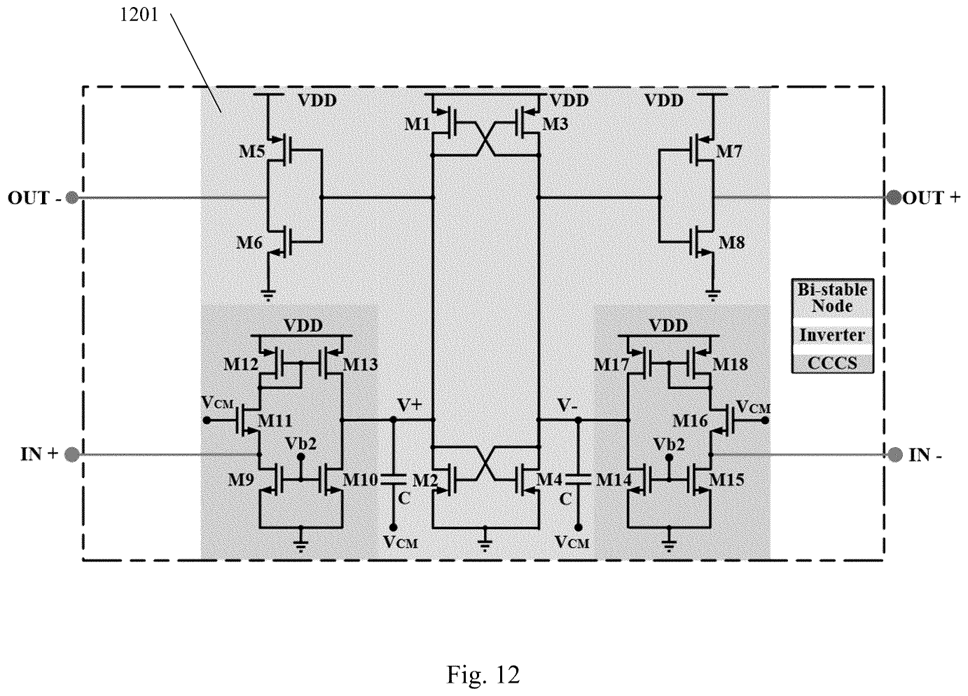

As contemplated herein, in some embodiments, the quantization of a QuBRIM node can be performed by simple logic gates (e.g., an inverter 1201 as shown in FIG. 12 illustrating an example schematic of a QuBRIM node). Alternatively, if more precision is required, a high-gain comparator, such as a regenerative latch, could be used. Similar to BRIM, it is apparent from from Equation 8 why QuBRIM tends to seek a (local) minimum of the objective term (−Σ_{i<j} Jᵢⱼvⱼvᵢ). Although the first summation term in Equation 8 does not take the same form as the Ising formula of Equation 1, it is apparent they become equivalent (up to a multiplicative constant) when voltages vᵢ bifurcate to ±1 due to the ZIV diode's effect and its P(vᵢ) double-well profile with two stable equilibrium points at or close to ±1. Although the quantized values Q(vᵢ) can be directly coupled to the capacitors of other nodes, this would likely produce large voltage swings across the terminals of R-PMOS resistors and likely cause non-linearity errors similar to the BRIM. In contrast to BRIM, QuBRIM in some embodiments adopts a current mode coupling. The coupling currents (Q(vᵢ)/Rᵢⱼ) are summed into a constant voltage node (e.g., a virtual ground node of an amplifier) with the help of a current conveyor, CCCS shown in FIG. 12. The current conveyor then mirrors this current sum into the capacitor C of the Nᵢ node. Therefore, all R-PMOS coupling resistors see a constant voltage magnitude (e.g., +V_{dd}/2) across their terminals rendering them inherently linear.

Quantizing nodal variables vᵢ to binary values before they are connected to the CU array and other nodes allows a straightforward multiplication of the quantized variables Q(vᵢ) by using, for example, XNOR logic gates to achieve multi-body interactions. For example, if assuming that a 4-spin objective function with cubic terms to be minimized is H=−J₁₂₃σ₁σ₂σ₃−J₁₂₄σ₁σ₂σ₄−J₁₃₄σ₁σ₃σ₄−J₂₃₄σ₂σ₃σ₄, the 4-node QuBRIM that minimizes the function H is constructed from the set of differential equations shown in Equation 13 below, where

$${R}_{i j k} = \frac{{R}_{c}}{{J}_{i j k}} ,$$

XNOR(a,b) is a 2-input exclusive-NOR logic gate, and

V_{CM} is a common-mode voltage typically equal to half of the power supply voltage. The left-hand side of Equation 13 represents a current into the nodal capacitance of node Nᵢ, which is equal to the sum of all currents from coupling resistors Rᵢⱼₖ and the ZIV diode's current.

$$C \frac{d {v}_{i}}{d t} = [ {\sum }_{j \neq i} {\sum }_{k \neq j} \frac{XNOR ( Q ( {v}_{j} ) , Q ( {v}_{k} ) ) - {V}_{C M}}{{R}_{i j k}} - {g}_{ZIV} ( {v}_{i} ) ] \qquad Equation 13$$

This approach can be extended to construct a QuBRIM machine that minimizes an objective function including Ising terms of not only arbitrary order (higher than two) but also an Ising formulation that includes mixed-order terms as well. It is also to be understood that an all-to-all QuBRIM with, for example, cubic terms would require O(N³) hardware resources in terms of CUs and O(N²) in terms of XNOR gates. There are several area efficient designs for XNOR gates (e.g., a 3-transistor XNOR in as shown in S, et al., 2016 3rd International Conference on Advanced Computing and Communication Systems (ICACCS), 2016), indicating that the area penalty would be largely due to the O(N³) CU array.

### System Level Design

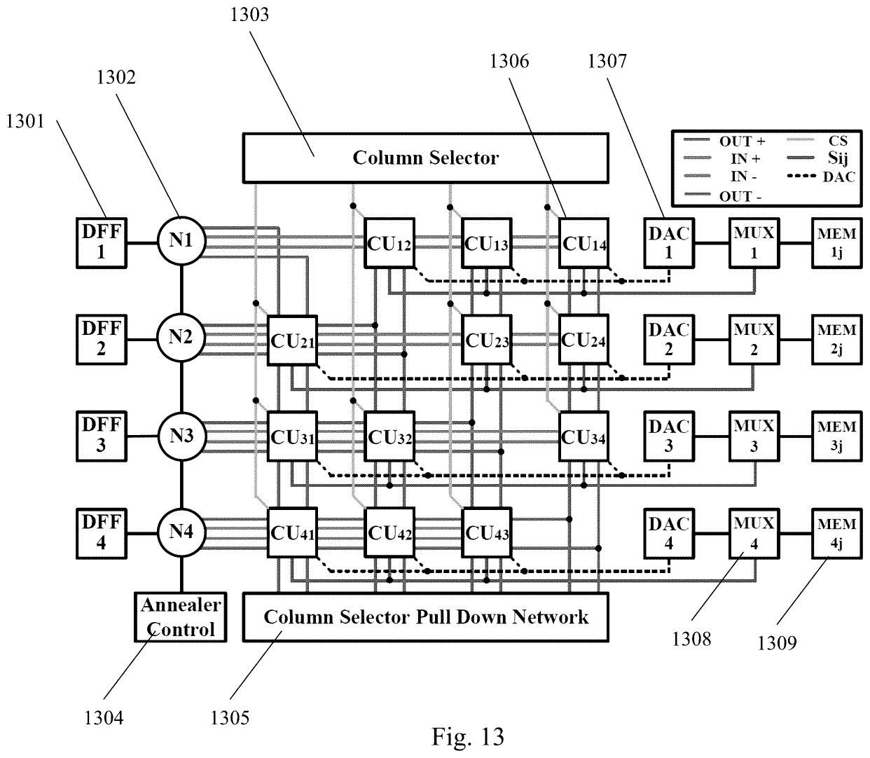

An exemplary QuBRIM system is illustrated in FIG. 13 and can be viewed as a group of subsystems as follows: The first subsystem is the nodes and coupling units: At the left of the diagram are the bistable nodes 1302 (Nᵢ). Each of them contains two capacitors to perform the differential operations. The nodes are connected to each other through a mesh of coupling units 1306 (CU) and each node has four terminals, the inputs IN+ and IN− that receive currents from other nodes, and the outputs OUT+ and OUT− generate quantized voltage signals that are coupled to other nodes. The detailed working principles of these two components will be discussed further below. The D Flip-Flop array next to the nodes comprises a set of one D-Flip-Flop 1301 per node, and is used to store the spin configuration when necessary.

The second subsystem is the programming units. Both the initial nodal values and the coupling resistance are programmable. To the right of the coupling unit array is the programming array. This array consists of digital memory 1309 for storing the weights which drive an array of digital-to-analog converters (DACs) 1307. A small number of such DACs 1307 are sufficient to program all the coupling units in a time-interleaved fashion. In the figure, we show N DACs are shown programming the N×(N−1) coupling units. In such a configuration, corresponding column selectors and pulldown logic 1303, 1306 are needed, which are shown above and below the coupling units.

The third subsystem is the perturbation units. As the complexity of graphs grows and the number of local minima in the Ising formulation increases, a machine that follows a gradient descent is more likely to end up at a local energy minimum. One possible way to escape local minima is by flipping the polarity of some of the spins. However, this scheme requires some monitoring blocks to detect and change the polarity of each node, which dramatically increases the hardware complexity. The disclosed device instead randomly chooses a node and briefly clips it to one of the supply rails. The nodal spin then either maintains its current state or swaps to the opposite state in a certain time interval. This scheme is referred to as “spin-fix annealing.” The control signals are sent by the Annealer Control unit 1304 in FIG. 13. The occurrence of spin-fix is more frequent at the beginning and gradually reduces. This approach makes sense because when the system's energy approaches its global minimum, it is less likely for it to escape it by a single spin-fix.

### Circuit Level Design

The following is a discussion of one embodiments of a detailed circuit implementation of the disclosed design, mainly focusing on the analog core part, i.e., a QuBRIM node and couplers.

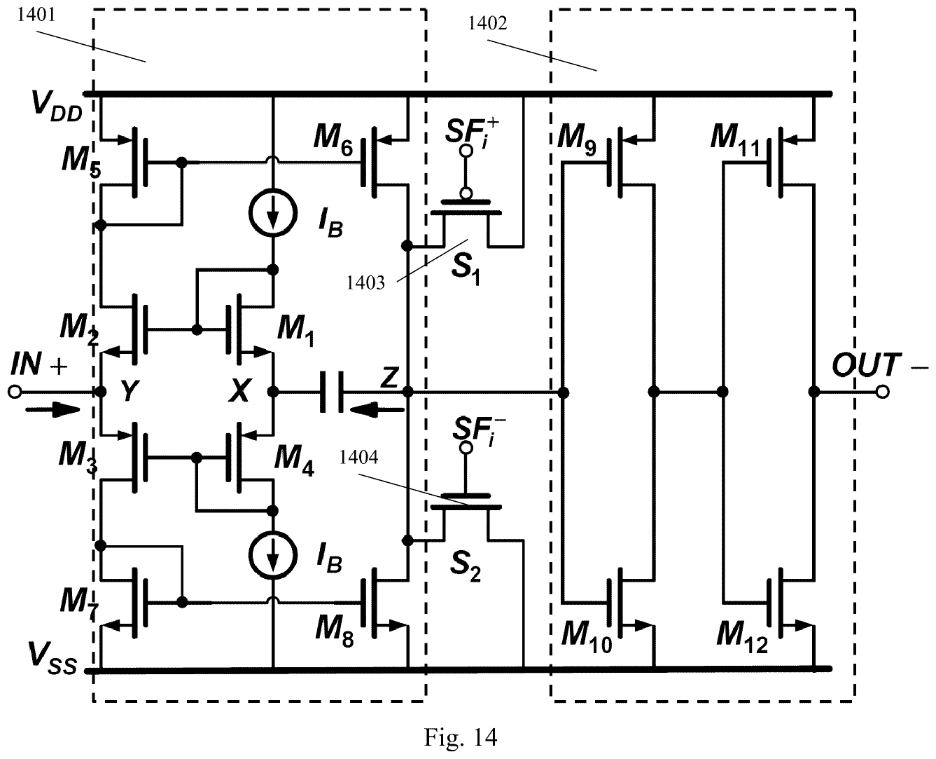

Although embodiments may refer to one specific implementation, for example the implementation shown in FIG. 14, it is understood that the present disclosure contemplates alternative designs using equivalent circuit elements to perform the functions disclosed herein.

With reference to FIG. 14, a half circuit of one QuBRIM node (e.g. 1302 in FIG. 13) is shown. In order to achieve cross coupling, the QuBRIM node has to be differential. The depicted circuit comprises three core functional sub-circuits, namely, a current conveyor, a quantizer, and spin fix switches. Each sub-circuit is described in detail below.

The current conveyor is constructed as a class AB current conveyor (see Wilson, International Journal of Electronics, 1992), denoted as 1401, and which is formed by M₁-M₈ in FIG. 14. The detailed working principle is as follows: current sources I_{B} set the biasing voltages for M₁-M₄, these four transistors then form a local feedback loop, which forces the voltage at junction X to follow that of junction Y. As a result, the biasing currents in the left branch and middle branch are the same. M₅-M₆ and M₇-M₅ form two pairs of current mirrors, which convey the input current to the output in a class AB manner. The main advantage of this circuit is that the Slew-Rate is unlimited and the input current can be larger than the biasing current. When a large Iᵢₙ flows into node X, M₅ and M₁ are off, M₄ and M₇ sink all the input current. On the other hand, when a large Iᵢₙ flows out of node X, M₄ and M₇ are off, and M₅ and M₁ source all the input current. For QuBRIM, node Y is fixed at V_{CM} such that the input current signal depends only on neighboring nodal voltages, i.e., node X is virtually grounded. Note that the directions of Iᵢₙ and Iout are opposite, however, thanks to the fully differential property of QuBRIM, swapping the polarity of the outputs is needed in some embodiments.

As the name of the disclosed design suggests, the voltage signal on the capacitor of one node is quantized before sending to the neighboring nodes. Because our system operates in a continuous time fashion, the quantizer 1402 can be simply constructed with two inverters connected in series. To increase the driving ability and decrease delay, the fan-out design metric is adopted. As shown in FIG. 14, M₉ and M₁₀ form the first inverter whereas M₁₁ and M₁₂ form the second inverter with larger aspect ratios compared to the former one.

Two pairs of switches (1403, 1404) are connected to the two capacitors in one QuBRIM node to configure the initial spins of the system before the machine's states are allowed to evolve in seeking an energy minimum. Another function of these switches is applying spin fix perturbation. SF₁⁺ and SF₁⁻ are non-overlapping signals used to control S₁ and S₂, respectively whereas, whereas due to differential operation, the same signals control S₂ and S₁, respectively in the other half circuit of the QuBRIM node.

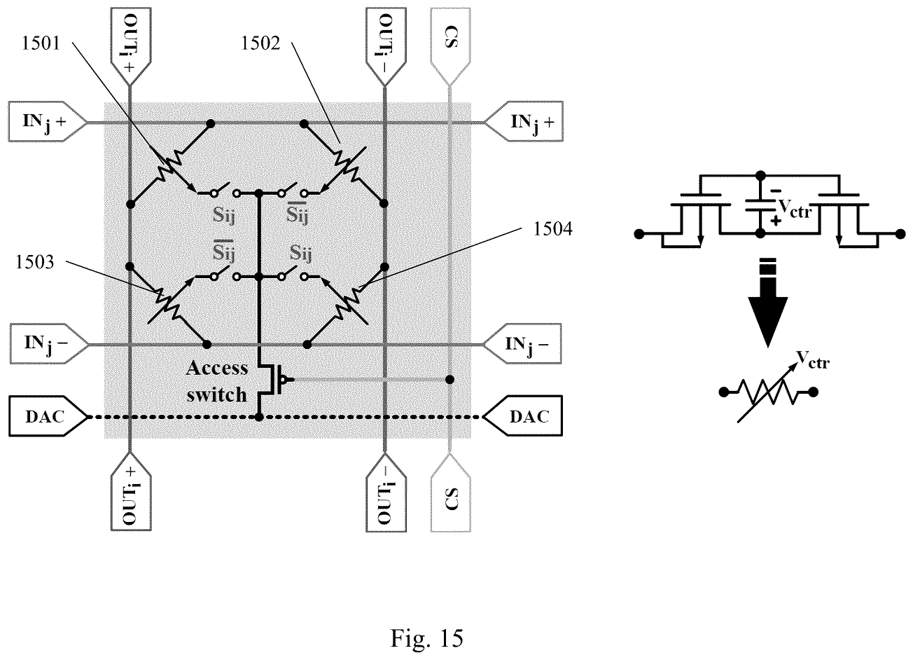

A detail view of an exemplary coupling unit is shown in FIG. 15. Because of the unidirectional coupling design, there are two separate coupling units (CU) connecting node Nᵢ to Nⱼ:CUᵢⱼ and CUⱼᵢ. The coupling coefficient of both directions are of course the same (Jᵢⱼ=Jⱼᵢ). Each node has separate input and output terminals (two each for fully-differential coupling), as shown in different colors in FIG. 13. Similarly, each CU also has four input/output terminals, with one pair of coupling resistors (1501, 1503) connecting the same polarity input/output nodes (parallel coupling) and another pair (1502, 1504) to establish antiparallel coupling, as shown on the left in FIG. 15. Depending on the polarity of the coupling coefficient (Jᵢⱼ), only one pair of the resistors is turned on, which is controlled by Sᵢⱼ and its complementary signal. The color schemes in FIG. 15 are matched to the system-level block diagram of FIG. 13, where CS represents the column selector signal. On the right is an implementation of an exemplary programmable coupling resistor, where V_{ctr} is the biasing voltage.

For a fully-connected network, the number of coupling units grows quadratically with the number of nodes, and the coupling units are expected to occupy the largest portion of the chip area. Therefore, implementing coupling elements as on-chip physical resistors, which tend to be large in area, is impractical. Instead, two back-to-back connected p-type transistors are used in the disclosed embodiment to form a pseudo-resistor that shares a similar I-V characteristic as a physical resistor, as shown on the right in FIG. 15. The source-gate biasing voltage (V_{ctr}) held by the capacitor essentially sets the resistance of the pseudoresistor which can be tuned through the DAC. For example, to establish a negative (anti-parallel) coupling, the gates of the upper-right (1502) and lower-left (1504) pseudo-resistors are biased to a non-zero voltage (V_{dac}), while the gates of 1501 and 1503 are biased at 0V (GND).

One drawback of this implementation is that it only provides moderate linearity. As the terminal voltage exceeds a certain range, its resistance varies a lot, which may affect the machine's coupling precision and overall solution quality. However, when used in QuBRIM, the pseudo-resistor becomes inherently linear thanks to the fact that the magnitude of its terminal voltage remains constant at V_{dd}/2 at all times. As can be seen in the schematics, one terminal of the pseudo-resistor is always fixed at V_{CM}=V_{dd}/2 while the other terminal is connected to the quantizer's output which could only take values V_{DD} or 0V, resulting in a terminal voltage across the pseudo-resistor of ±V_{dd}/2.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the system and method of the present invention. The following working examples therefore, specifically point out the exemplary embodiments of the present invention, and are not to be construed as limiting in any way the remainder of the disclosure.

### Simulation

Simulations were run using the disclosed design to evaluate its performance, at both the circuit level and the behavioral level. Because of the straightforward connection to the Ising model, the Max-Cut problem was adopted as the benchmark. First the design was validated on the circuit level on small-size graph problems, then performance was compared between the disclosed design and other existing Ising machines on large graphs.

### Circuit Level Validation

A 32-node QuBRIM was designed in a 45 nm generic process design kit (GPDK) and simulated in Virtuoso Analog Design Environment (ADE), both provided by Cadence. The test bench contained 20 fully-connected graphs with binary weights. The best Max-Cuts for these graphs are known. First, spin-fix annealing was disabled and each graph was simulated 100 times with different initial spin configurations. In the next simulations, spin-fix annealing was enabled. For a fair comparison, the same initial spin configurations were used, but different spin-fix sequences were applied in each run. Also, the occurring probability of spin-fix was set to decrease linearly over time, as discussed above.

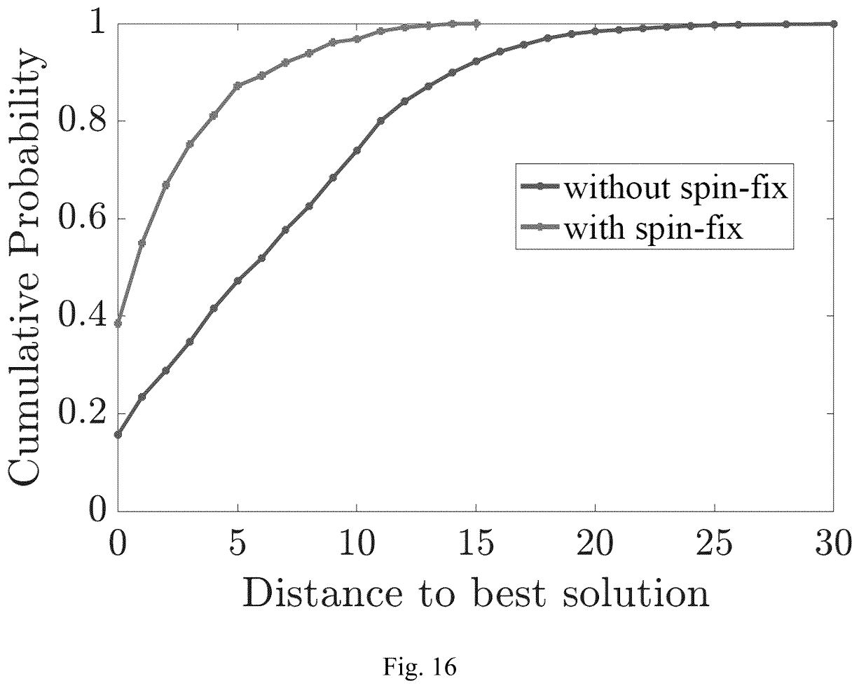

Results indicate that the disclosed machine always ends in local minima, whether spin-fix annealing is on or off, which is expected. The distances to the best solution were then used as the figure of merit and these were plotted over time in FIG. 16. As can be seen, the spin-fix annealing technique significantly improves the solution quality. Specifically, the probability of finding the best solutions (0 distance) increases from 15.7% to 38.6%.

For those that are not the best solutions, the average distance reduces from 8.09 to 3.75 after applying spin-fix annealing. FIG. 16 is a graph of the Cumulative Probability Distribution of distance from the best Max-Cut for 32-node graphs for a simulation time of 200 ns. Note that the best Max-Cut for the 32-node graph is found by enumerating and comparing all 2³² possible solutions.

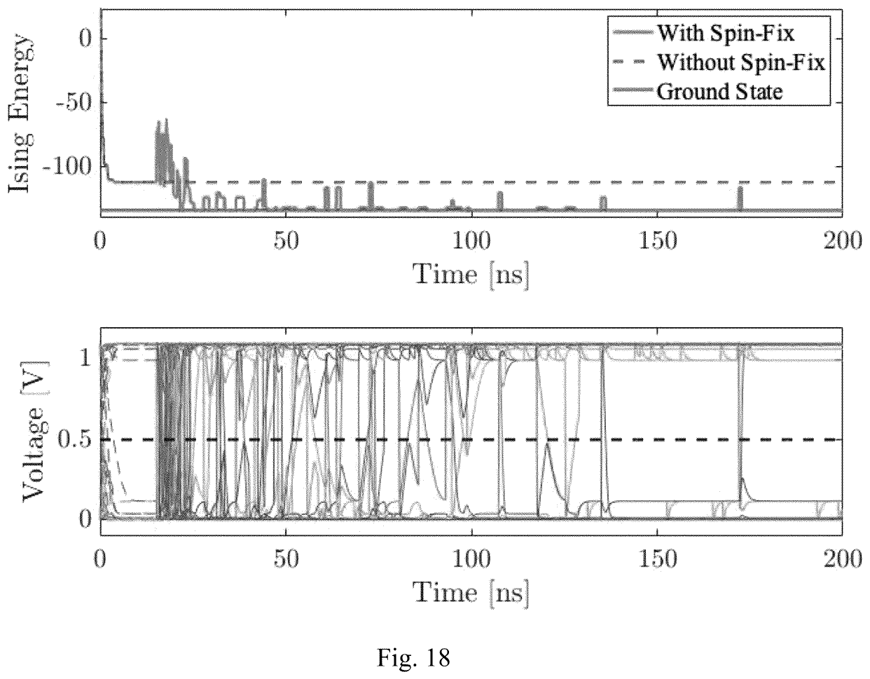

The transient behavior of the system was also explored. A graph was randomly chosen from the above test bench and the change of the Ising energy as time advances was captured, as shown in the top graph of FIG. 18. The top graph of FIG. 18 shows Ising energy vs. time, while the bottom graph shows the transient voltage of each node. As shown in FIG. 18, the machine reaches a local minimum at roughly 15 ns (dashed section), then spin-fix annealing kicks in (solid section).It can be seen that the Ising energy decreases quickly and monotonically at the beginning (where spin-fix annealing is off) and flattens out once the machine settles to a local minimum. This is consistent with the voltage waveforms below where the nodes interact with each other at the beginning then enter steady states after a short time (dashed section).

On the other hand, when spin-fix annealing is enabled, the machine becomes busier in exploring many attraction regions within the energy landscape. Once it reaches the vicinity of the global minimum, spin-fix of a single or a few nodes will only temporally increase the energy level. However, they will be quickly pulled back to the global minimum by the rest of the nodes. This behavior can also be observed from the voltage waveforms near the end of the annealing time.

Comparison to other Ising Machines

It is also worth comparing the disclosed design with other existing Ising machines. The following machines were evaluated:

1) D-Wave: The 2000Q was used, which is the latest quantum annealer. Jobs were launched using the API provided by D-Wave. For each graph problem, 50 samples were collected. In terms of timing, no constraints were specified, and D-Wave default values were used-specifically: 20 μs, 198 μs, 21 μs, and 11.7 ms respectively for annealing, data readout, inter-sample delay, and qubits programming.

2) OIM: is an electronic Oscillator-based Ising Machine. For simulation, the Kuramoto model was used based on code provided in Wang, et al., 2019.

3) ASA: refers to a number of related designs of Accelerated Simulated Annealers. These accelerators use virtual spins and are straightforward to model based on the descriptions in literature. The version used in this example had 30,000 nominal spins. In this design, the coupling followed a near-neighbor pattern dubbed the King's graph. All nodes were grouped into 4 groups. Every annealing step (0.22 μs), nodes in one of the groups processed in parallel: they read off the neighbor's spin and the associated weights to compute whether keeping the same spin or inverting its current spin provides lower energy in the neighborhood. In addition, random bit flips similar to those in standard simulated annealing algorithms were also adopted.

Because most of the compared designs are based on the behavioral model, for a fair comparison, a behavioral model was also created for the disclosed design. Fully-connected tiny graphs were generated with binary edge weights, and node sizes ranging from 16 to 32 (in increments of 4). Each node size had 20 sample graphs, for a total of 100 graphs. For these graphs, all possible spin combinations were enumerated to determine the actual maximum cut.

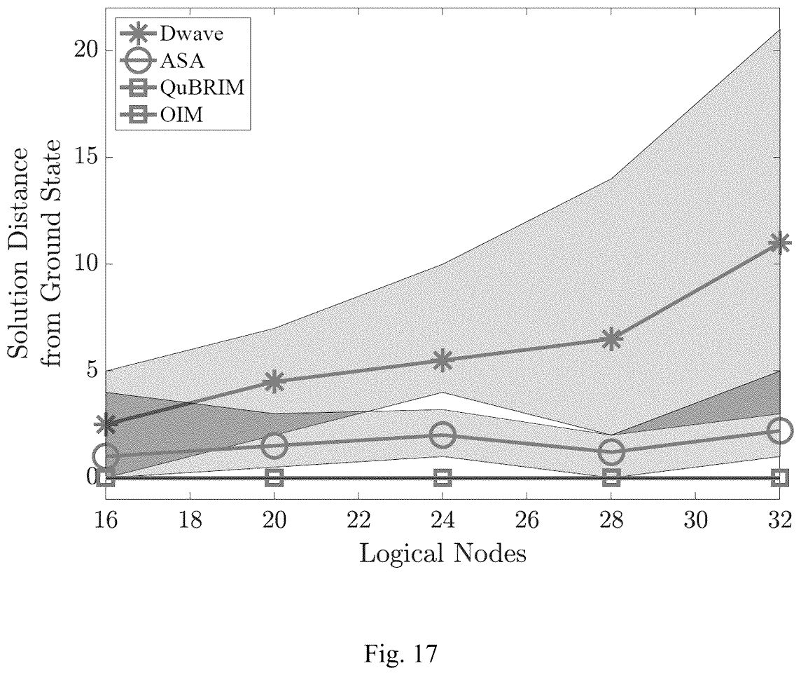

FIG. 17 shows the solution quality of different systems on tiny graphs. All the systems were tested for an annealing time of 20 μs (to match the D-wave annealing time). The best of 50 runs were taken for each graph. Using these graphs it was verified that QuBRIM, OIM, and ASA can reach ground states. D-Wave did not reach the ground state, with the best solution having a distance of 6. ASA and QuBRIM can both achieve ground state often, however, QuBRIM can do so with a higher probability (68%) than ASA (25%). Note that systems like D-wave and ASA are not all-to-all coupled machines. So, to fit the graphs on these systems it is necessary to preprocess them using a minor embedding algorithm. The preprocessing takes a non-trival amount of time, but this time was ignored when doing the comparison.

Finally, the machined was simulated with even larger graphs to test its scalability. Again, the behavioral model was adopted due to the non-trival amount of time when simulating large graphs at the circuit level. The original Gset graphs from Stanford Ye, https://web.stanford.edu/˜yyye/yyye/Gset were used. These graphs have between 800 and 20,000 nodes. The edges as well as the weights of such edges were generated probabilistically, sometimes between +1 and −1, and sometimes all +1. QuBRIM was compared with an ASA with unlimited nodes to map the problem as well as the classic Simulated Annealing (SA) algorithm. The whole test was done on server cluster nodes of Intel Xeon Platinum 8268 CPUs at 2.9 GHz with 371 GB of RAM. Table 2 below summarizes the results for benchmarks of Gset with no more than 1000 nodes. For QuBRIM, the distances ranged from 0 to 16, with a mean of 5.45 and a median of 4. In contrast, the distance for ASA (1 ms) ranged from 0 to 42 with a mean of 15.1, and a median of 14. Additionally, the distance for SA (2 secs) ranged from 0 to 2 with a mean of 0.3, and a median of 0. SA obtained slightly better results, but note that it takes 6 orders of magnitude longer than QuBRIM. Increasing annealing time for QuBRIM may improve quality but becomes extremely expensive to simulate.

TABLE 2

| | Best | Ref. | QuBRIM | ASA | SA |
|---|---|---|---|---|---|
| G01 | 11624 | §‡† | 0 | 42 | 0 |
| G02 | 11620 | § | 0 | 38 | 0 |
| G03 | 11622 | § | 1 | 1 | 0 |
| G04 | 11646 | §‡† | 0 | 23 | 0 |
| G05 | 11631 | §‡† | 0 | 27 | 0 |
| G06 | 2178 | § | 0 | 2 | 0 |
| G07 | 2006 | § | 6 | 21 | 0 |
| G08 | 2005 | § | 1 | 9 | 0 |
| G09 | 2054 | § | 4 | 1 | 0 |
| G10 | 2000 | § | 4 | 1 | 1 |
| G11 | 564 | §‡† | 12 | 8 | 0 |
| G12 | 556 | §‡† | 10 | 4 | 0 |
| G13 | 582 | §‡† | 10 | 6 | 0 |
| G14 | 3063 | § | 11 | 16 | 1 |
| G15 | 3050 | ‡† | 3 | 7 | 0 |
| G16 | 3052 | §‡† | 13 | 27 | 0 |
| G17 | 3047 | ‡† | 12 | 24 | 1 |
| G18 | 992 | ‡† | 2 | 12 | 1 |
| G19 | 906 | § | 1 | 7 | 0 |
| G20 | 941 | §‡† | 0 | 0 | 0 |
| G21 | 931 | § | 4 | 8 | 0 |
| G43 | 6660 | § | 1 | 26 | 0 |
| G44 | 6650 | ‡ | 1 | 11 | 0 |
| G45 | 6654 | ‡ | 5 | 5 | 0 |
| G46 | 6649 | §‡ | 6 | 16 | 0 |
| G47 | 6657 | ‡ | 3 | 18 | 0 |
| G51 | 3847 | ‡ | 12 | 21 | 0 |
| G52 | 3851 | ‡ | 16 | 28 | 1 |
| G53 | 3850 | ‡ | 14 | 20 | 1 |
| G54 | 3851 | ‡ | 14 | 24 | 2 |

A bistable, resistively-coupled Ising Machine with quantized nodal interaction is disclosed herein. The simulation results indeed demonstrate its capability of solving challenging computation problems such as Max-Cut problems. Utilizing only simple building blocks makes the disclosed topology more scalable and inexpensive as compared to other desk-size (or even room size) Ising machines. With the help of spin-fix annealing, the performance of the disclosed machine is further improved. Not only does the probability of reaching Max-Cut increase by a factor of 2.6, but the solution quality is significantly better when the global optimum is not reached.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

### REFERENCES

The following publications are incorporated herein by reference in their entirety.

A. Sharma, R. Afoakwa, Z. Ignjatovic, and M. Huang, “Increasing Ising machine capacity with multi-chip architectures,” in Proceedings of the 49th Annual International Symposium on Computer Architecture, ser. ISCA '22. New York, NY, USA: Association for Computing Machinery, 2022, p. 508-521. [Online]. Available: https://doi.org/10.1145/3470496.3527414

Afoakwa, R., Zhang, Y., Vengalam, U., Ignjatovic, Z. & Huang, M. Brim: Bistable resistively coupled Ising machines. In International Symposium on High-Performance Computer Architecture (2021).

B. Erbagci, N. E. C. Akkaya, C. Teegarden, and K. Mai, “A 275 Gbps AES encryption accelerator using ROM-based S-boxes in 65 nm,” in 2015 IEEE Custom Integrated Circuits Conference (CICC), 2015, pp. 1-4.

B. Wilson, “Tutorial review trends in current conveyor and current-mode amplifier design,” International Journal of Electronics, vol. 73, no. 3, pp. 573-583, 1992. [Online]. Available: https://doi.org/10.1080/00207219208925692

Böhm, F., Verschaffelt, G. & Van der Sande, G. A poor man's coherent Ising machine based on opto-electronic feedback systems for solving optimization problems. Nature Communications 10, 3538 (2019). URL https://doi.org/10.1038/s41467-019-11484-3.

C. Johnson, D. H. Allen, J. Brown, S. Vanderwiel, R. Hoover, H. Achilles, C.-Y. Cher, G. A. May, H. Franke, J. Xenedis et al., “A wire-speed power tm processor: 2.3 GHz 45 nm soi with 16 cores and 64 threads,” in 2010 IEEE International Solid-State Circuits Conference (ISSCC). IEEE, 2010, pp. 104-105.

C. Roques-Carmes, Y. Shen, C. Zanoci, M. Prabhu, F. Atieh, L. Jing, T. Dubcek, C. Mao, M. R. Johnson, V. Ceperic, J. D. Joannopoulos, D. Englund, and M. Soljacic, “Heuristic recurrent algorithms for photonic Ising machines,” Nature Communications, vol. 11, no. 1, p. 249, 2020.

F. Ma, J.-K. Hao, and Y. Wang, “An effective iterated tabu search for the maximum bisection problem,” Computers & Operations Research, vol. 81, pp. 78-89, 2017.

H. Kaul, M. A. Anders, S. K. Mathew, G. Chen, S. K. Satpathy, S. K. Hsu, A. Agarwal, and R. K. Krishnamurthy, “14.4 a 21.5 m-queryvectors/s 3.37 nj/vector reconfigurable k-nearest-neighbor accelerator with adaptive precision in 14 nm tri-gate cmos,” in 2016 IEEE International Solid-State Circuits Conference (ISSCC). IEEE, 2016, pp. 260-261.

Honjo, T. et al. 100,000-spin coherent ising machine. Science Advances 7, eabh0952 (2021).

Inagaki, T. et al. A coherent ising machine for 2000-node optimization problems. Science 354, 603-606 (2016).

Isakov, S., Zintchenko, I., Rønnow, T. & Troyer, M. Optimised simulated annealing for ising spin glasses. Computer Physics Communications 192, 265-271 (2015). URL http://dx.doi. org/10.1016/j.cpc.2015.02.015.

J. Cai, W. G. Macready, and A. Roy, “A practical heuristic for finding graph minors,” ArXiv, vol. abs/1406.2741, 2014.

K. Takata, A. Marandi, R. Hamerly, Y. Haribara, D. Maruo, S. Tamate, H. Sakaguchi, S. Utsunomiya, and Y. Yamamoto, “A 16-bit coherent ising machine for one-dimensional ring and cubic graph problems,” Scientific Reports, vol. 6, no. 1, p. 34089, 2016.

Lucas, A. Ising formulations of many np problems. Frontiers in Physics 2, 5 (2014).

M. Vidyasagar, Nonlinear System Analysis. SIAM, 1978.

M. Yamaoka, C. Yoshimura, M. Hayashi, T. Okuyama, H. Aoki, and H. Mizuno, “24.3 20k-spin ising chip for combinational optimization problem with cmos annealing,” in 2015 IEEE International Solid-State Circuits Conference-(ISSCC) Digest of Technical Papers, February 2015, pp. 1-3.

N. P. Jouppi, C. Young, N. Patil, D. Patterson, G. Agrawal, R. Bajwa, S. Bates, S. Bhatia, N. Boden, A. Borchers, R. Boyle, P.-1. Cantin, C. Chao, C. Clark, J. Coriell, M. Daley, M. Dau, J. Dean, B. Gelb, T. V. Ghaemmaghami, R. Gottipati, W. Gulland, R. Hagmann, C. R. Ho, D. Hogberg, J. Hu, R. Hundt, D. Hurt, J. Ibarz, A. Jaffey, A. Jaworski, A. Kaplan, H. Khaitan, D. Killebrew, A. Koch, N. Kumar, S. Lacy, J. Laudon, J. Law, D. Le, C. Leary, Z. Liu, K. Lucke, A. Lundin, G. MacKean, A. Maggiore, M. Mahony, K. Miller, R. Nagarajan, R. Narayanaswami, R. Nᵢ, K. Nix, T. Norrie, M. Omernick, N. Penukonda, A. Phelps, J. Ross, M. Ross, A. Salek, E. Samadiani, C. Severn, G. Sizikov, M. Snelham, J. Souter, D. Steinberg, A. Swing, M. Tan, G. Thorson, B. Tian, H. Toma, E. Tuttle, V. Vasudevan, R. Walter, W. Wang, E. Wilcox, and D. H. Yoon, “In-Datacenter Performance Analysis of a Tensor Processing Unit,” SIGARCH Comput. Archit. News, vol. 45, no. 2, p. 1-12, June 2017.

P. I. Bunyk, E. M. Hoskinson, M. W. Johnson, E. Tolkacheva, F. Altomare, A. J. Berkley, R. Harris, J. P. Hilton, T. Lanting, A. J. Przybysz, and J. Whittaker, “Architectural Considerations in the Design of a Superconducting Quantum Annealing Processor,” IEEE Transactions on Applied Superconductivity, vol. 24, no. 4, pp. 1-10, 2014.

P. L. McMahon, A. Marandi, Y. Haribara, R. Hamerly, C. Langrock, S. Tamate, T. Inagaki, H. Takesue, S. Utsunomiya, K. Aihara, R. L. Byer, M. M. Fejer, H. Mabuchi, and Y. Yamamoto, “A fully programmable 100-spin coherent ising machine with all-to-all connections,” Science, vol. 354, no. 6312, pp. 614-617, 2016.

Q. Wu and J.-K. Hao, “Memetic search for the max-bisection problem,” Computers & Operations Research, vol. 40, no. 1, pp. 166-179, 2013.

R. Hamerly, T. Inagaki, P. L. McMahon, D. Venturelli, A. Marandi, T. Onodera, E. Ng, C. Langrock, K. Inaba et al., “Scaling advantages of all-to-all connectivity in physical annealers: the coherent ising machine vs. d-wave 2000q,” arXiv: arXiv: 1807.00089, 2018.

R. Hamerly, T. Inagaki, P. L. McMahon, D. Venturelli, A. Marandi, T. Onodera, E. Ng, C. Langrock, K. Inaba, T. Honjo et al., “Experimental investigation of performance differences between coherent ising machines and a quantum annealer,” Science advances, vol. 5, no. 5, p. eaau0823, 2019.

R. Harris, M. W. Johnson, T. Lanting, A. J. Berkley, J. Johansson, P. Bunyk, E. Tolkacheva, E. Ladizinsky, N. Ladizinsky, T. Oh, F. Cioata, I. Perminov, P. Spear, C. Enderud, C. Rich, S. Uchaikin, M. C. Thom, E. M. Chapple, J. Wang, B. Wilson, M. H. S. Amin, N. Dickson, K. Karimi, B. Macready, C. J. S. Truncik, and G. Rose, “Experimental investigation of an eight-qubit unit cell in a superconducting optimization processor,” Phys. Rev. B, vol. 82, p. 024511, July 2010.

S, J., M. B. P. & MP, S. An ultra-low area and full-swing output 3t xnor gate using 45 nm technology. In 2016 3rd International Conference on Advanced Computing and Communication Systems (ICACCS), vol. 01, 1-4 (2016).

S. Dutta, A. Khanna, A. S. Assoa, H. Paik, D. G. Schlom, Z. Toroczkai, A. Raychowdhury, and S. Datta, “An ising hamiltonian solver based on coupled stochastic phase-transition nano-oscillators,” Nature Electronics, vol. 4, no. 7, pp. 502-512, 2021.

S. Kirkpatrick, C. D. Gelatt, and M. P. Vecchi, “Optimization by simulated annealing,” science, vol. 220, no. 4598, pp. 671-680, 1983.

S. Song, W. Tang, T. Chen, and Z. Zhang, “LEIA: A 2.05 mm2 140 mW lattice encryption instruction accelerator in 40 nm CMOS,” in 2018 IEEE Custom Integrated Circuits Conference (CICC), 2018, pp. 1-4.

T. G. J. Myklebust, “Solving maximum cut problems by simulated annealing,” 2015.

T. Wang and J. Roychowdhury, “OIM: Oscillator-Based Ising Machines for Solving Combinatorial Optimisation Problems,” 2019.

Tajalli, A., Leblebici, Y. & Brauer, E. Implementing ultra-high-value floating tunable cmos resistors. Electronics Letters 44 (2008).

Takemoto, T., Hayashi, M., Yoshimura, C. & Yamaoka, M. 2.6 a 2 by 30k-spin multichip scalable annealing processor based on a processing-in-memory approach for solving large-scale combinatorial optimization problems. In IEEE International Solid-State Circuits Conference (2019).

Tatsumura, K., Dixon, A. R. & Goto, H. Fpga-based simulated bifurcation machine. In 2019 29th International Conference on Field Programmable Logic and Applications (FPL), 59-66 (2019).

Y. Chen, T. Luo, S. Liu, S. Zhang, L. He, J. Wang, L. Li, T. Chen, Z. Xu, N. Sun, and O. Temam, “DaDianNao: A Machine-Learning Supercomputer,” in 2014 47th Annual IEEE/ACM International Symposium on Microarchitecture, December 2014, pp. 609-622.

Y. Takeda, S. Tamate, Y. Yamamoto, H. Takesue, T. Inagaki, and S. Utsunomiya, “Boltzmann sampling for an XY model using a nondegenerate optical parametric oscillator network,” Quantum Science and Technology, vol. 3, no. 1, p. 014004, November 2017.

Y. Yamamoto, K. Aihara, T. Leleu, K.-i. Kawarabayashi, S. Kako, M. Fejer, K. Inoue, and H. Takesue, “Coherent ising machines-optical neural networks operating at the quantum limit,” npj Quantum Information, vol. 3, no. 1, p. 49, 2017.

Y. Ye. G-set benchmark. [Online]. Available: https://web.stanford.edu/˜yyye/yyye/Gset

Z. Varty, “Simulated annealing overview,” 2017. [Online]. Available: https://www.lancaster.ac.uk/pg/varty/RTOne.pdf

What is claimed is:

1. A computation node, comprising:
an input;
an output;
a bistable node, comprising an input and an output, the output configured to have at least two equilibrium output voltages;
a first buffer circuit, having an input and an output, the buffer input connected to the output of the bistable node and the buffer output connected to the output of the computation node, the buffer circuit configured to provide a first output voltage when a voltage at the buffer input is below a threshold, and a second output voltage when the voltage at the buffer input is above the threshold; and
a current conveyor node having an input connected to the input of the computation node and an output connected to the input of the bistable node, the current conveyor configured to hold its input at a constant voltage and mirror current received at the input into the input of the bistable node.

2. The computation node of claim 1, wherein the first buffer circuit comprises an inverter.

3. The computation node of claim 1, the computation node further comprising:
a second, inverting output; and
a second buffer circuit having an input connected to an inverting output of the bistable node, the inverting output of the bistable node configured to have an inverse value of the output of the bistable node, the second buffer circuit further comprising an output connected to the second inverting output of the computation node.

4. The computation node of claim 3, wherein the first and second buffer circuits each comprise an inverter.

5. The computation node of claim 1, further comprising:
a second, inverting input; and
a second current conveyor node having an input connected to the second inverting input of the computation node and an output connected to a second input of the bistable node, the current conveyor configured to hold its input at a constant voltage and mirror current received at the input into the second input of the bistable node.

6. A network comprising at least first and second computation nodes as defined in claim 1, further comprising a coupling node connecting the output of the first computation node to the input of the second computation node.

7. The network of claim 6, wherein the coupling node comprises a resistor.

8. The network of claim 6, wherein the coupling node comprises a pseudo-resistor.

9. A network of resistively-coupled computation nodes, comprising:
at least one computation node, each comprising:
an input;
an output;
a bistable node, comprising an input and an output, the output configured to have at least two equilibrium output voltages;
a first inverter having an input and an output, the inverter input connected to the output of the bistable node and the inverter output connected to the output of the computation node; and
a current conveyor node having an input connected to the input of the computation node and an output connected to the input of the bistable node; and
a resistive coupling connected to the output of the computation node.

10. The network of claim 9, the at least one computation node comprising first and second computation nodes;
wherein the input of the second computation node is connected to the input of the first computation node.

11. The network of claim 10, wherein the output of the first computation node and the output of the second computation node are connected to a multiplication node configured to multiply the outputs and provide the multiplied output as a multiplication node output.

12. The network of claim 11, wherein the multiplication node comprises an exclusive NOR gate.
